(19) United States
(12) Patent Application Publication
(10) Pub. No.: US 2025/0225304 A1
(43) Pub. Date: Jul. 10, 2025

(54) DEVICE HAVING ALTERNATING ROWS OF CORRESPONDING FIRST AND SECOND ROW-ARCHITECTURES AND METHOD OF MANUFACTURING SAME

(71) Applicant: TAIWAN SEMICONDUCTOR MANUFACTURING COMPANY, LTD., Hsinchu (TW)

(72) Inventors: Chun-Hsuan WANG, Hsinchu (TW); Ching-Yu HUANG, Hsinchu (TW); Wei-Cheng LIN, Hsinchu (TW); Jiann-Tyng TZENG, Hsinchu (TW)

(21) Appl. No.: 18/408,782

(22) Filed: Jan. 10, 2024

(51) Int. Cl. G06F 30/392; G06F 30/3947; G06F 30/398

(52) U.S. Cl. CPC G06F 30/392; G06F 30/3947; G06F 30/398

(57) ABSTRACT

A device includes: alternating first rows and second rows correspondingly including first cell regions and second cell regions, each of the first cell regions and second cell regions correspondingly including active regions; in a first metallization layer over the active regions, each of the first cell regions and the second cell regions include first and second power grid (PG) segments, and one or more routing (RTE) segments; and in a first buried metallization layer under the active regions, each of the first cell regions includes first and second buried PG (BPG) segments, and each of the second cell regions includes one or more buried local interconnect (BLI) structures; and each of the first cell regions is free from including a BLI structure.

### BACKGROUND

The semiconductor integrated circuit (IC) industry produces a wide variety of analog and digital devices to address issues in a number of different areas. Developments in semiconductor process technology nodes have progressively reduced component sizes and tightened spacing resulting in progressively increased transistor density. ICs have become smaller.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. The drawings are not to scale, unless otherwise disclosed.

FIGS. 1A-1C are corresponding layout diagrams of a device, in accordance with some embodiments.

FIGS. 2A-2C are corresponding cross-sectional views of a device, in accordance with some embodiments.

FIGS. 3A-3F are corresponding layout diagrams of corresponding devices, in accordance with some embodiments.

FIGS. 4A-4F are corresponding layout diagrams of corresponding devices, in accordance with some embodiments.

FIG. 5A is a schematic circuit diagram, in accordance with some embodiments.

FIGS. 5A-5B are corresponding layout diagrams of a device, in accordance with some embodiments.

FIGS. 6 and 7A-7B are flowcharts of corresponding methods of manufacturing a memory device, in accordance with some embodiments.

FIG. 8 is a block diagram of an electronic design automation (EDA) system in accordance with some embodiments.

FIG. 9 is a block diagram of an integrated circuit (IC) manufacturing system, and an IC manufacturing flow associated therewith, in accordance with some embodiments.

### DETAILED DESCRIPTION

The following disclosure discloses many different embodiments, or examples, for implementing different features of the subject matter. Examples of components, materials, values, steps, operations, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows include embodiments in which the first and second features are formed in direct contact, and further include embodiments in which additional features are formed between the first and second features, such that the first and second features are in indirect contact. In addition, the present disclosure repeats reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, are used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus is otherwise oriented (rotated 90 degrees or at other orientations) and the spatially relative descriptors used herein are likewise interpreted accordingly. In some embodiments, the term standard cell structure refers to a standardized building block included in a library of various standard cell structures. In some embodiments, various standard cell structures are selected from a library thereof and are used as components in a layout diagram representing a circuit.

In some embodiments, a device includes: alternating first rows and second rows correspondingly including first cell regions and second cell regions, each of the first cell regions and second cell regions correspondingly including active regions; in a first metallization layer over the active regions, each of the first cell regions and the second cell regions include first and second power grid (PG) segments, and one or more routing (RTE) segments; and in a first buried metallization layer under the active regions, each of the first cell regions includes first and second buried PG (BPG) segments, and each of the second cell regions includes one or more buried local interconnect (BLI) structures; and each of the first cell regions is free from including a BLI structure.

According to another approach, BM0_LI structures are not used, which leads to a problem of competition for M0_rte segments, i.e., a problem of M0 routability congestion. The other approach mitigates the problem of M0 routability congestion by making a given cell region wider, i.e., increasing the pitch of the given cell region. However, widening cell regions to reduce M0 routability congestion has a disadvantage of reducing cell region density of devices which include the widened cell regions. By contrast, at least some embodiments provide BM0_LI structures in even rows according to the architecture of alternating row-arrangements disclosed herein, which has a benefit of reducing M0 routability congestion and a benefit of not having to increase cell pitch, as compared to the other approach.

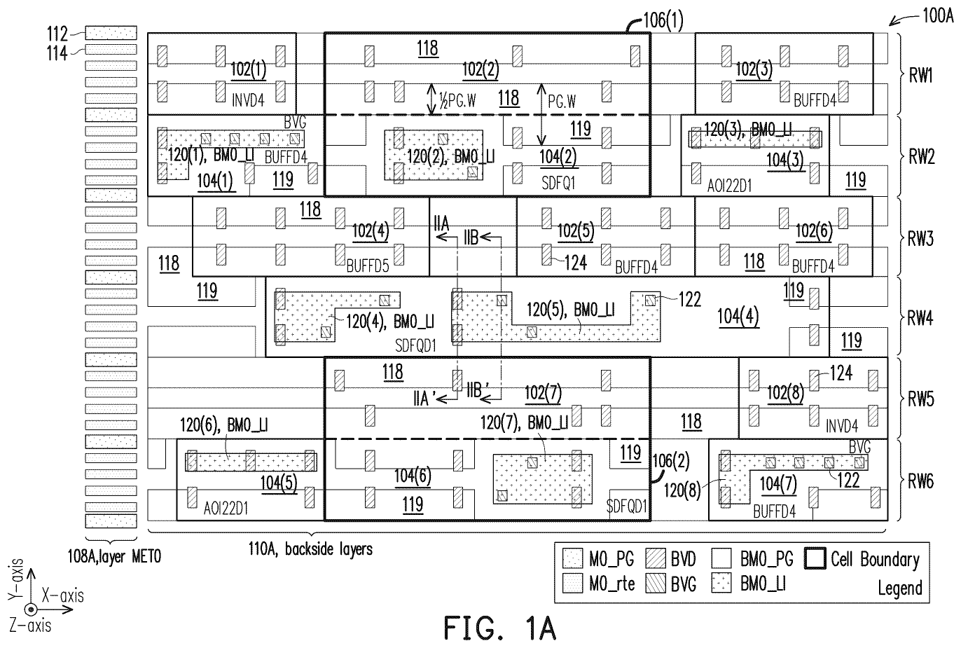

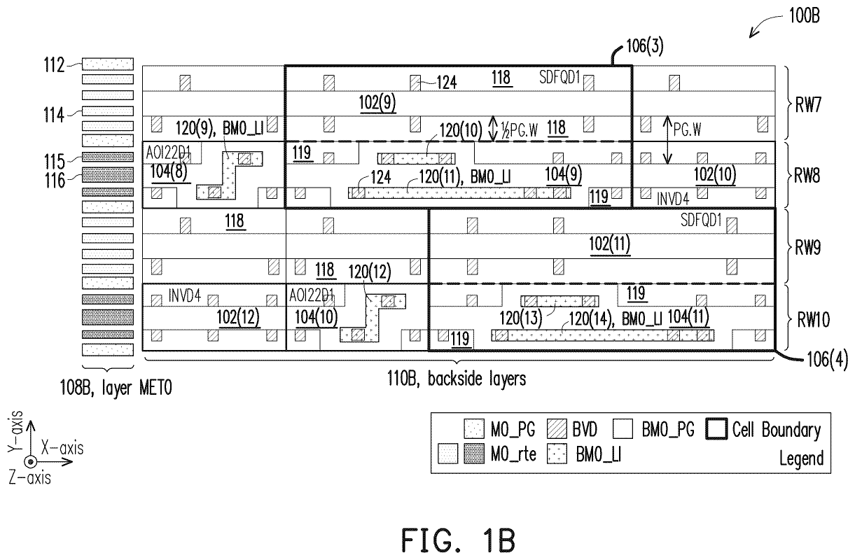

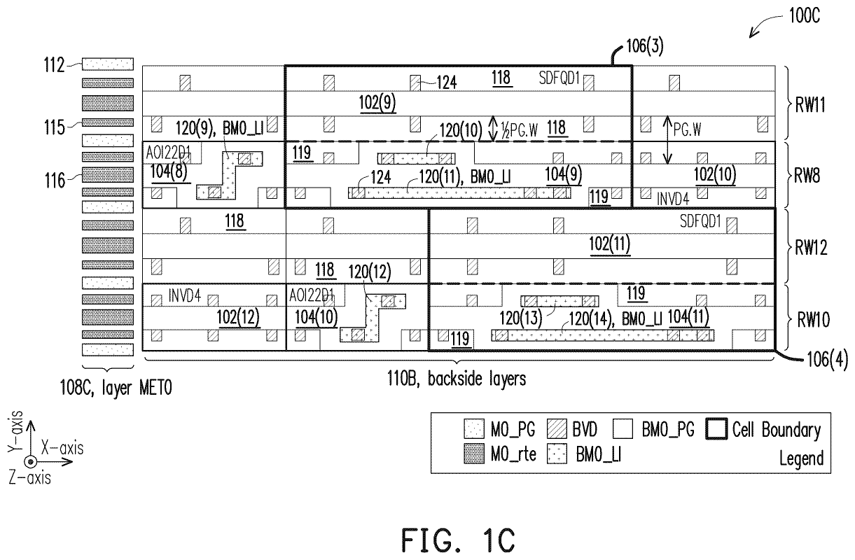

FIG. 1A is a layout diagram of a device 100A, in accordance with some embodiments.

The layout diagram of FIG. 1A is representative of a transistor-based device, e.g., a semiconductor device. Structures in the device are represented by patterns (also known as shapes) in the layout diagram. For simplicity of discussion, elements in the layout diagram of FIG. 1A (and also in other layout diagrams disclosed herein) will be referred to as if they are structures rather than patterns per se. For example, instances of pattern 112 in FIG. 1A represent instances of an M0 routing segment. In the following discussion, instances of element 112 are referred to as instances of M0 routing segment 112 rather than as instances of M0 routing pattern 11.

In FIG. 1A, as well as in other layout diagrams disclosed herein, an orthogonal Cartesian coordinate system is assumed in which a first direction is parallel to the X-axis, a second direction is parallel to the Y-axis and a third direction is parallel to the Z-axis. A layout diagram per se is a top view. Shapes in the layout diagram are two-dimensional relative to, e.g., the X-axis and the Y-axis, whereas the device being represented is three-dimensional. As such, a shape in such layout diagrams is described as having a width/length relative to the X-axis and a height relative to the Y-axis. Relative to the Z-axis, a front side of the device being represented in the layout diagram is stacked on a back side of the device. In some embodiments, the first to third directions correspond to directions other than the X-axis, Y-axis and Z-axis.

Typically, relative to the Z-axis, the device is organized as a stack of layers in which are located corresponding structures, i.e., to which belong corresponding structures. Each shape in the layout diagram represents, more particularly, a component in a corresponding layer of the corresponding device. Also, typically, the layout diagram represents relative depth, i.e., positions along the Z-axis, of shapes and corresponding layers by superimposing a second shape on a first shape so that the second shape at least partially overlaps the first shape. Some structures are stacked in a layout diagram along the Z-axis; however, the stacking order along the Z-axis is distorted in some respects relative to the corresponding device for simplicity of illustration. For example, in FIGS. 1A-1C, BM0_LI structures 120(1)-120(x) are shown over corresponding instances of BVG contact 122 and BVD contact 124.

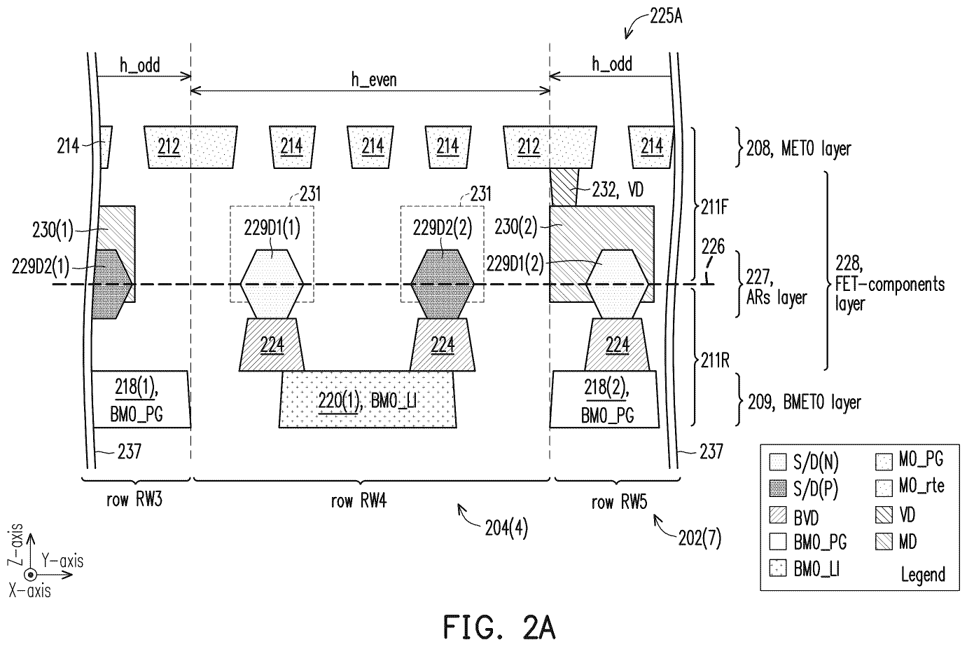

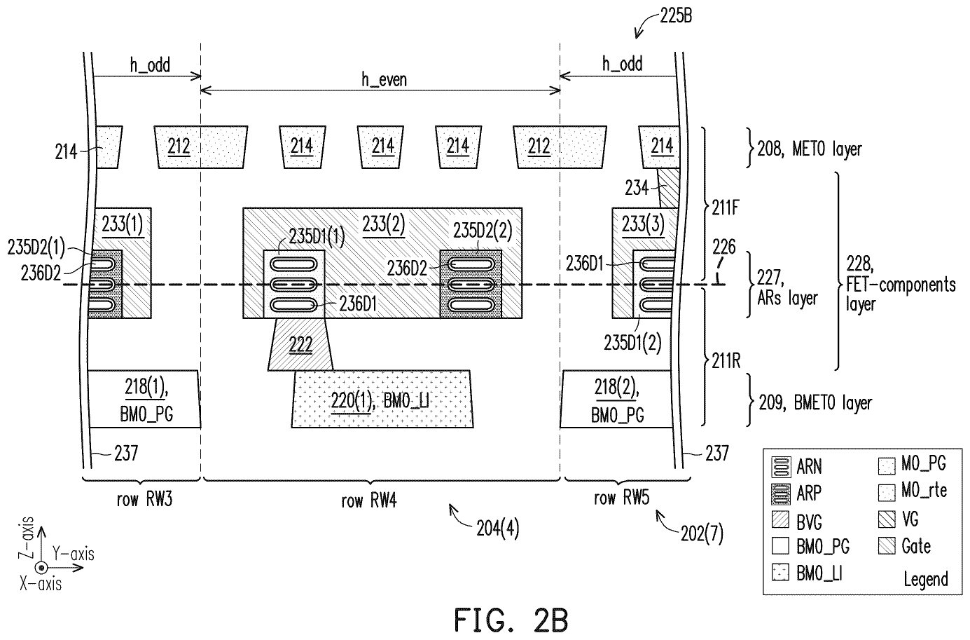

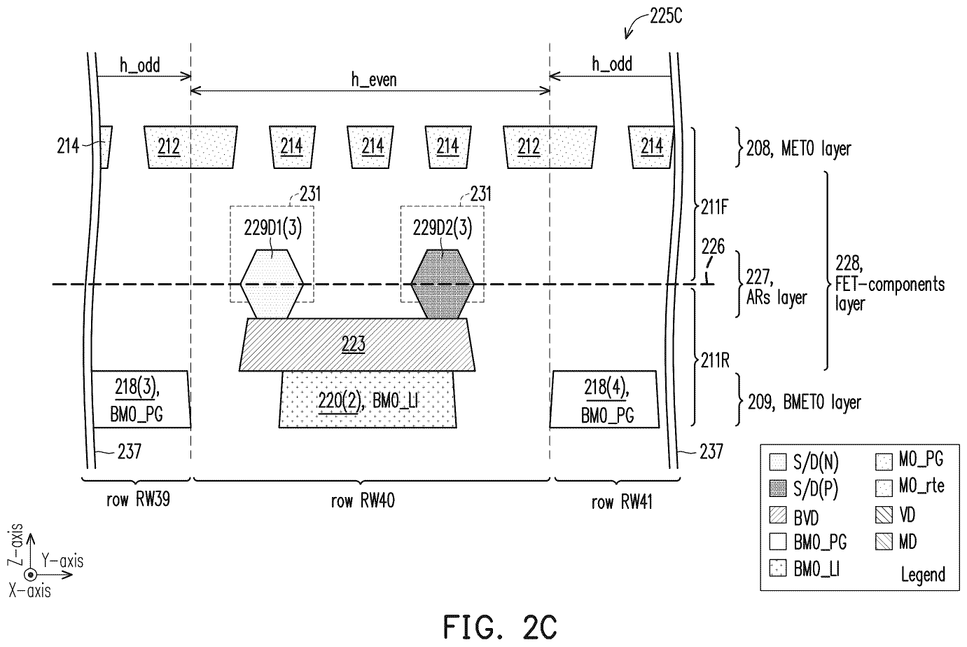

In FIG. 1A, each of section line IIA-IIA′ and section line IIB-IIB′ extends parallel to the Y-axis. Section line IIA-IIA′ corresponds to the cross-sectional view 225A of FIG. 2A. Section line IIB-IIB′ corresponds to the cross-sectional view 225B of FIG. 2B.

Layout diagrams vary in terms of the amount of detail represented. In some circumstances, selected layers of a layout diagram are combined/abstracted into a single layer, e.g., for purposes of simplification. Alternatively, and/or additionally, in some circumstances, not all layers of the corresponding semiconductor device are represented, i.e., selected layers of the layout diagram are omitted, e.g., for simplicity of illustration. Alternatively, and/or additionally, in some circumstances, not all elements of a given depicted layer of the corresponding semiconductor device are represented, i.e., selected elements of the given depicted layer of the layout diagram are omitted, e.g., for simplicity of illustration. FIG. 1A and the other layout diagrams disclosed herein are examples of layout diagrams in which selected layers and/or selected elements of depicted given layers, have been omitted. In some embodiments, the layout diagram of FIG. 1A is part of a larger layout diagram.

Regarding FIG. 1A, and more generally for the present disclosure, a numbering convention is assumed as follows: a first layer of metallization over active regions (FIGS. 2A-2B) of the transistors is numbered as is layer zero, and is referred to as layer MET0; a first layer of interconnection (not shown) over layer MET0 is referred to as layer VIA0; a first layer of metallization under the active regions (FIGS. 2A-2B) of the transistors, i.e., the first buried layer, is numbered as buried layer zero and is referred to as layer BMET0; and a first layer of interconnection (not shown) under layer BMET0 is referred to as layer BVIA0 (not shown). In some embodiments, depending upon the numbering convention of the corresponding process node by which a device is manufactured, the first layer over the active regions (FIGS. 2A-2B) of the transistors is numbered as layer one and is referred to as layer MET1, the first layer of interconnection (not shown) over layer MET1 is referred to as layer VIA1, the first layer of metallization under the active regions (FIGS. 2A-2B) of the transistors is numbered as buried layer one and is referred to as layer BMET1, and the first layer of interconnection (not shown) under layer BMET0 is referred to as layer BVIA1.

In FIG. 1A, the layout diagram shows portions 108A and 110A of device 100A. Portion 108A of device 100A represents structures in layer MET0. Portion 110A of device 100A represents structures in backside layers, i.e., in layers under the active regions (FIGS. 2A-2B) of the transistors. In FIG. 1A, for simplicity of illustration, portion 108A is shown to the left of portion 110A rather than over portion 110A. Also, for simplicity of illustration, the size/length of the structures in portion 108A relative to the X-axis is truncated.

Device 100A includes first cell regions and second cell regions. For simplicity of illustration, some but not all instances of the first cell regions are numbered, namely 102(1)-102(8). For simplicity of illustration, some but not all of the second of cell regions are numbered, namely 104(1)-104(7).

Each of the first cell regions and each of the second cell regions correspondingly has a width relative to the X-axis and a height relative to the Y-axis. Device 100A is arranged in rows RW1-RW6 that extend parallel to the X-axis.

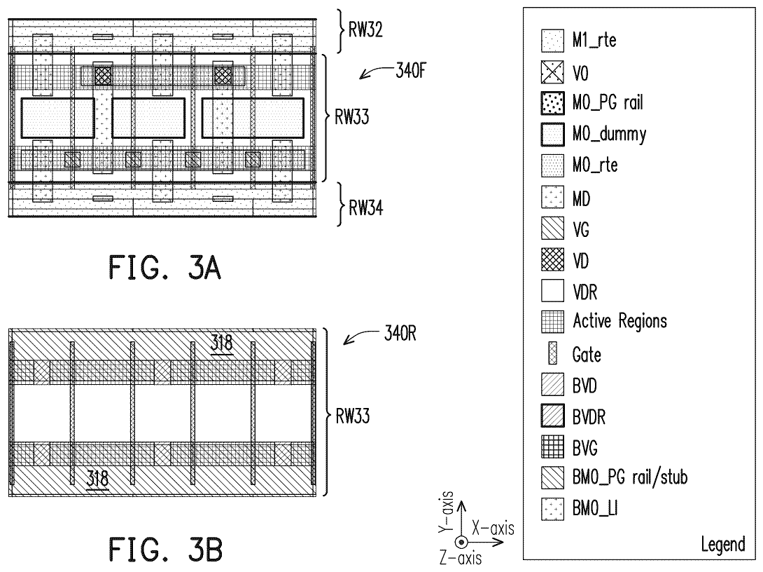

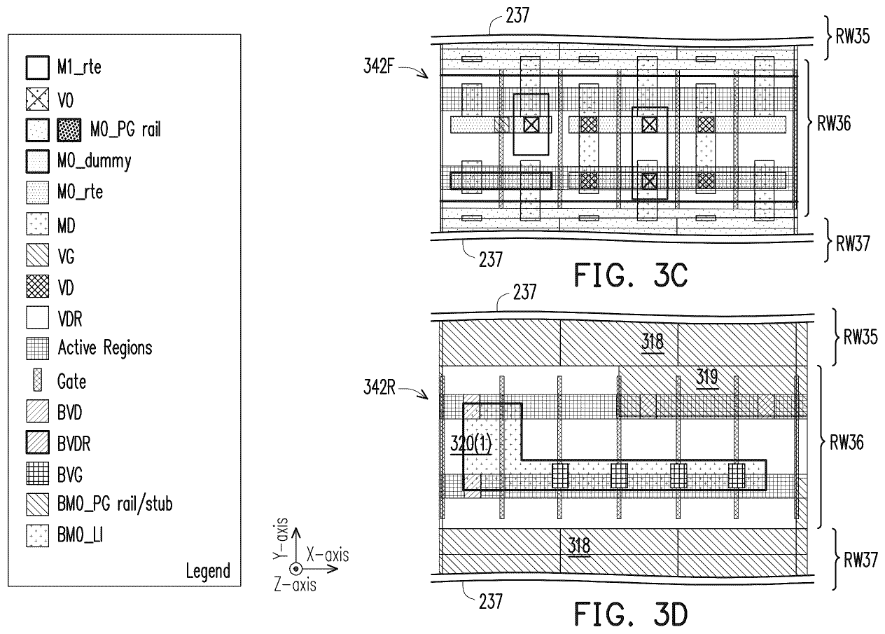

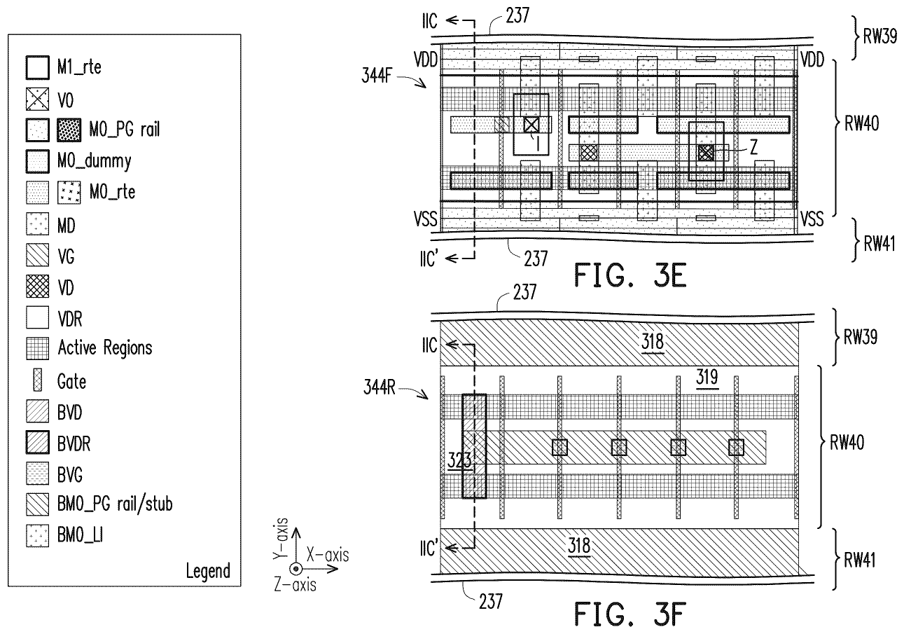

Each of the first cell regions and each of the second cell regions is in a corresponding one of rows RW1-RW6. Accordingly, in some embodiments, each of the first cell regions and each of the second cell regions has a height equal to a height of a single row and is described as a single row-height (or single height) cell region. Only the first cell regions are in the odd rows, namely RW1, RW3 and RW5. The second cell regions are in the even rows, namely RW2, RW4 and RW6. The second cell regions are excluded from being in the odd rows. In some embodiments, one or more instances of an even row includes one or more first cell regions in addition to one or more second cell regions, e.g., row RW8 of FIGS. 1B-1C includes first cell region 102(10) in addition to second cell regions 104(8) and 104(9). Accordingly, in some embodiments, device 100A of FIG. 1A is described as having an architecture of alternating row-arrangements, i.e., alternating rows of corresponding first and second row-architectures. In some embodiments, the architecture of alternating row-arrangements exhibits a benefit of facilitating coupling one or more nodes in a given second cell region in an even row to a BM0_PG rail in an adjoining odd row (FIG. 3D).

First cell region 102(2) is stacked on second cell region 104(2) relative to the Y-axis and together comprise a tall cell region 106(1). First cell region 102(7) is stacked on second cell region 104(6) relative to the Y-axis and together comprise a tall cell region 106(2). As such, each of tall cell regions 106(1) and 106(2) has a height equal to a height of two single rows, i.e., a double row, and is described as a double row-height (or double height) cell region. In some embodiments, tall cell regions 106(1)-106(2) are described as tall cell regions whereas cell regions 102(1)-102(8) and 104(1)-104(7) are described as short cell regions.

Each of first cell regions 102(1) and 102(8) represents an INVD4 cell region. In some embodiments, INVD4 is an alphanumeric text string used as an adjective that is intended to connote that each of first cell regions 102(1) and 102(8) is an inverter cell region for which a current-driving/sourcing strength of the cell region is 4D, where D is a unit of driving strength. In some embodiments, a value of unit driving strength D is determined by, e.g., the design rules and scale of the corresponding semiconductor process technology node.

Each of first cell regions 102(3) and 102(5)-102(6) (FIGS. 3A-3B), and each of second cell regions 104(1) and 104(7) (FIGS. 3C-3D), represents a BUFFD4 cell region. First cell region 102(4) represents a BUFFD5 cell region. In some embodiments, BUFFDx is an alphanumeric text string used as an adjective that is intended to connote that the corresponding cell region is a buffer cell region. for which the driving strength of the cell region is DX, where X is a multiple of the unit driving strength D. Each of first cell regions 102(3) and 104(5)-104(6) has x=4 such that the driving strength is D4. First cell region 102(4) has x=5 such the driving strength is D5. BUFFD4 cell region 104(7) is substantially the same as BUFFD4 cell region 104(1).

Each of second cell regions 104(3) and 104(5) represents an AOI22D1 cell region. In some embodiments, AOID22D1 is an alphanumeric text string used as an adjective that is intended to connote that the corresponding cell region is an AND-OR-INVERT cell region for which the AND gate portion has two inputs, the OR gate has two inputs and the driving strength of the cell region is the unit driving strength D. AOI22D1 cell region 104(5) is substantially the same as AOI22D1 cell region 104(3).

Each of tall cell regions 106(1) and 106(2) and second cell region 104(4) represents an SDFQD1 cell region. In some embodiments, SDFQD1 is an alphanumeric text string used as an adjective that is intended to connote that the corresponding cell region is a type of D flip-flop (FF), namely a scan-insertion D FF (SDFQ) for which the driving strength is the unit driving strength D. In some embodiments, an SDFQ cell region is used, e.g., to implement design for testing (DFT). An SDFQ is a D flip-flop that includes a multiplexer to controllably select between an input D during normal operation and a scan input during scan/test operation. Scan flip-flops, e.g., SDFQs, are used for device testing.

Portion 108A of device 100A includes conductive segments in layer MET0 that extend parallel to the X-axis, namely instances of M0_PG segment 112 and instances of M0_rte segment 114. Relative to the Y-axis, a height of each instance of M0_rte segment 114 is less than a height of each instance of M0_PG segment 112.

Relative to the Y-axis, each of a top boundary and a bottom boundary of each of rows RW1-RW6 is straddled by a corresponding instance of M0_PG segment 112. Each instance of M0_PG segment 112 is a part of a corresponding rail in a power grid (PG) of device 100A. Accordingly, each instance of M0_PG segment 112 is described as an instance of M0_PG segment 112 and is configured for carrying/conducting a corresponding one of reference voltages of device 100A, e.g., VDD, VSS, or the like. Relative to the Y-axis, a top area of each of the first cell regions and each of the second cell regions is overlapped by a portion of a corresponding instance of M0_PG segment 112. Similarly, a bottom area of each of the first cell regions and each of the second cell regions is overlapped by a portion of a corresponding instance of M0_PG segment 112.

By contrast, instances of M0_rte segment 114 are routing segments that form portions of signal paths and so are configured for carrying/conducting corresponding routing signals for/of circuits implemented correspondingly by an instance of the first cell region, an instance of the second cell region, tall cell regions 106(1)-106(2), or the like. Examples of routing signals include input/output (I/O) signals, data signals, control signals, or the like. Instances of M0_rte segment 114 are referred to as M0_rte segment 114. Relative to the Y-axis, each instance of M0_rte segment is narrower/shorter than each instance of M0_PG segment 112.

Layer MET0 is organized according to a first grid that includes first reference lines (alpha tracks) (not shown) which extend parallel to the X-axis. Instances of M0_rte segment 114 are aligned correspondingly to the alpha tracks. For a given one of the alpha tracks, one or more instances of M0_rte segment 114 are aligned to the given alpha track and are distributed relative to the X-axis. Relative to the X-axis, whether a given section of the given alpha track is populated with a given instance of M0_rte segment 114, as well as a determination of a length of the given instance of M0_rte segment 114, depends on the portion of the corresponding first cell region or second cell region which is under the given section.

Each of rows RW1-RW6 has four alpha tracks. Accordingly, each of the first cell regions or the second cell regions correspondingly therein can have (but does not necessarily have) one or more instances of M0_rte segment 114 aligned to each of the four alpha tracks for the corresponding row. For simplicity of illustration, relative to the Y-axis, FIG. 1A shows adjacent instances of M0_PG segment 112 as being separated by four instances of M0_rte segment 114. In some embodiments, each of rows RW1-RW4 is described as having a ‘four M0_rte segments per row’ architecture.

In FIG. 1A, portion 110A represents structures in backside layers, i.e., in layers under the active regions (FIGS. 2A-2B) of the transistors. Portion 110A includes: instances of a buried via-to-gate (BVG) contact 122; instances of a buried via-to-MD (BVD) contact 124; and conductive segments in layer BMET0 that extend parallel to the X-axis, namely instances of BM0 segment 118 and buried local intra-connect (BM0_LI) structures 120(1)-120(8).

As an intraconnect, each of BM0_LI structures 120(1)-120(8) couples nodes within a given cell region, i.e., on an intra-cell-region basis. In some embodiments, some of the BM0_LI structures are inter-connect structures (not shown) that couple one of more nodes of a first instance of the first cell region to a second instance of a first cell region, i.e., on an inter-cell-region basis.

In some embodiments, BVG contact 122 is a contact structure that couples a gate (FIG. 2B) to a BM0_LI structure. In some embodiments, BVD contact 124 is a contact structure that couples a source/drain (S/D) region (FIG. 2A) to a BM0_LI structure.

According to another approach, BM0_LI structures are not used, which leads to a problem of competition for M0_rte segments, i.e., a problem of M0 routability congestion. The other approach mitigates the problem of M0 routability congestion by making a given cell region wider, i.e., increasing the pitch of the given cell region. However, widening cell regions to reduce M0 routability congestion has a disadvantage of reducing cell region density of devices which include the widened cell regions. By contrast, at least some embodiments provide BM0_LI structures in even rows according to the architecture of alternating row-arrangements disclosed herein, which has a benefit of reducing M0 routability congestion and benefit of not having to increase cell pitch, as compared to the other approach.

Relative to the Y-axis, in each of first cell regions 102(1)-102(8): a top area is overlapped by a portion of a corresponding instance of BM0_PG segment 118; and, similarly, a bottom area is overlapped by a portion of a corresponding instance of BM0_PG segment 118. In each of rows RW1, RW3 and RW5, the corresponding instances of BM0_PG segment 118 span the entire row, and are referred to as BM0_PG rails in some embodiments. Relative to the Y-axis, each BM0_PG rail 118 has a height of ½PG.W.

In first cell regions 102(1)-102(8), and relative to the Y-axis: instances of BVD contact 124 are substantially overlapped by portions of corresponding instances of BM0_PG rail 118; and instances of BVG contact 122 are substantially overlapped by portions of corresponding BM0_LI structures 120(1)-120(8).

BM0_LI structures 120(1)-120(8) are correspondingly in even rows RW2, RW4 and RW6. Each of second cell regions 104(1)-104(7) includes at least one BM0_LI structure. As such, BM0_LI structures 120(1)-120(8) are correspondingly in second cell regions 104(1)-104(7). Some of the second cell regions include at least two BM0_LI structures. Examples of a second cell region including at least two BM0_LI structures include second cell regions 104(4), 104(9) and 104(11) which include BM0_LI structures 120(4) & 120(5), 120(10) & 120(11), and 120(13) & 120(14), or the like.

At least some of BM0_LI structures 120(1)-120(8), a portion that extends across a central zone of the corresponding second cell region. Examples of a BM0_LI structure having a portion that extends across a central zone of the corresponding second cell region include BM0_LI structures 120(1)-120(2), 120(4)-120 (50, 120(7)-120(9) and 120(12) in corresponding second cell regions 104(1)-104(2), 104(4), 104(4) and 104(6)-104(7), or the like.

In some embodiments, each of BM0_LI structures 120(1)-120(8) is described as an irregular polygon. In some embodiments, an irregular polygon is defined as a polygon for which not all sides have equal length and not all angles are equal.

In some embodiments, each of BM0_LI structures 120(1), 120(4), 120(5) and 120(8) is described as a concave polygon. In some embodiments, a concave polygon is defined as a polygon having at least one interior angle greater than 180 degrees (180°). Regarding a diagonal extending between first and second vertices of a polygon, in some embodiments, a concave polygon is defined as a polygon for which at least one diagonal is outside the polygon. In some embodiments, each of BM0_LI structures 120(1), 120(4) and 120(8) is described as a concave polygon having a P-shape. In some embodiments, each of BM0_LI structures 120(1), 120(4) and 120(8) is described as a concave polygon having an L-shape. In some embodiments, BM0_LI structure 120(5) is described as a concave polygon having a U-shape.

In some embodiments, each of BM0_LI structures 120(2)-120(3) and 120(6)-120(7) is described as a convex polygon. In some embodiments, a convex polygon is defined as polygon for which all interior angles are less than 180 degrees (180°). In some embodiments, a convex polygon is defined as a polygon for which all diagonals are inside the polygon.

In some embodiments, each of BM0_LI structures 120(2)-120(3) and 120(6)-120(7) is described as a rectangle.

Relative to the Y-axis, each of BM0_LI structures 120(2) and 120(7) is shorter than each of BM0_LI structures 120(2) and 120(7). In some embodiments, accordingly, each of BM0_LI structures 120(2) and 120(7) is described as a short-rectangle shape, and each of BM0_LI structures 120(2) and 120(7) is described as a tall-rectangle shape.

In some embodiments, relative to the Y-axis, each of BM0_LI structures 120(3) and 120(6) has a height equal to a minimum height for a conductive segment in the layer BMET0. In some embodiments, relative to the Y-axis, a minimum height for a conductive segment in the layer BMET0 is determined by, e.g., the design rules and scale of the corresponding semiconductor process technology node.

Relative to the Y-axis, one or more portions of each of even rows RW2, RW4 and RW6 include instances of BM0_PG segment 119. In each of even rows RW2, RW4 and RW6, none of the corresponding instances of BM0_PG segment 119 spans substantially the entire row such that instances of BM0_PG segment 119 are referred to as BM0_PG stubs in some embodiments.

Relative to the Y-axis, some of cell regions 104(1)-104(7) include instances of BM0_PG stub 119, e.g., cell regions 104(2), 104(4) and 104(6). By contrast, some of second regions 104(1)-104(7) are free from including instances of BM0_PG stub 119, e.g., second cell regions 104(1), 104(3), 104(5) and 104(7).

Where a first instance of BM0_PG rail 118 at the bottom area of a first cell region, e.g., first cell region 102(2), abuts a first instance of BM0_PG stub 119 at the top area of a second cell region, e.g., second cell region 104(2), the first instance of BM0_PG rail 118 and the first instance of BM0_PG stub 119 have a combined with of 2*½PG.W=PG.W.

Relative to the X-axis, second cell region 104(2) includes instances of BM0_PG stub 119 to the left and right of BM0_LI structure 120(2). Also, BM0_LI structure 120(2) is located asymmetrically within second cell region 104(2) relative to the X-axis, i.e., a center of BM0_LI structure 120(2) is shifted left of a center of second cell region 104(2).

Relative to the X-axis, the right side of second cell region 104(4) includes instances of BM0_PG stub 119. In second cell region 104(4), U-shaped BM0_LI structure 120(5) is between P-shaped BM0_LI structure 120(4) and the instances of BM0_PG stub 119.

Relative to the X-axis, second cell region 104(6) includes instances of BM0_PG stub 119 to the left and right of BM0_LI structure 120(7). Also, BM0_LI structure 120(7) is located asymmetrically within second cell region 104(7) relative to the X-axis, i.e., a center of BM0_LI structure 120(7) is shifted right of a center of second cell region 104(6).

Relative to an axis of symmetry parallel to the Y-axis, tall cell region 106(2) substantially represents a version of tall cell region 106(1) rotated 180 degrees (180°). As such, each of first cell region 102(7) and second cell region 104(6) correspondingly substantially represent first cell region 102(2) and second cell region 104(2) and rotated 180 degrees (180°).

In FIGS. 1A-1C: odd rows have a height h_odd (FIGS. 2A-2B); and even rows have a height h_even (FIGS. 2A-2B). In FIGS. 1A-1C, h_odd=h_even. In some embodiments, h_odd+h_even.

FIG. 1B is a layout diagram of a device 100B, in accordance with some embodiments.

Device 100B of FIG. 1B is similar to device 104A of FIG. 1A. For brevity, the discussion will focus on differences of device 100B as compared to device 100A rather than on similarities.

In FIG. 1B, the layout diagram shows portions 108B and 110B of device 100B. Portion 108B of device 100B represents structures in layer MET0. Portion 110B of device 100B represents structures in backside layers, i.e., in layers under the active regions (FIGS. 2B-2B) of the transistors.

For simplicity of illustration, some but not all instances of the first cell regions are numbered, namely 102(9)-102(11). For simplicity of illustration, some but not all of the second of cell regions are numbered, namely 104(8)-104(11).

In FIG. 1B, each of the first cell regions and each of the second cell regions is in a corresponding one of rows RW7-RW10. Only the first cell regions are in the odd rows, namely RW7 and RW9. The second cell regions are in the even rows, namely RW8 and RW110. The second cell regions are excluded from being in the odd rows. In some embodiments, one or more instances of an even row includes one or more first cell regions in addition to one or more second cell regions, e.g., row RW8 of FIGS. 1B-1C includes first cell region 102(10) in addition to second cell regions 104(8) and 104(9). As with device 100A, in some embodiments, device 100B of FIG. 1B is described as having an architecture of alternating row-arrangements, i.e., alternating rows of corresponding first and second row-architectures.

First cell region 102(9) is stacked on second cell region 104(9) relative to the Y-axis and together comprise a tall cell region 106(3). First cell region 102(11) is stacked on second cell region 104(11) relative to the Y-axis and together comprise a tall cell region 106(4).

Each of first cell regions 102(10) and 102(12) represents an INVD4 cell region. INVD4 cell region 102(12) is substantially the same as INVD4 cell region 102(10). Each of second cell regions 104(8) and 104(10) represents an AOI22D1 cell region. AOI22D1 104(10) is substantially the same as AOI22D1 104(8).

In FIG. 1B, each of tall cell regions 106(3) and 106(4) represents an SDFQD1 cell region. SDFQD1 cell region 106(4) is substantially the same as SDFQD1 cell region 106(3). As such, first cell region 102(9) of SDFQD1 106(3) is substantially the same as first cell region 102(11) of SDFQD1 106(4). Also, second cell region 104(9) of SDFQD1 106(3) is substantially the same as second cell region 104(11) of SDFQD1 106(4).

Portion 108B of device 100B includes M0_PG conductive segments in layer MET0 that extend parallel to the X-axis, namely instances of M0_PG segment 112, instances of M0_rte segments 115 and 116. Relative to the Y-axis, a height of each instance of M0_rte segment 115 is less than a height of each instance of M0_PG segment 112. Relative to the Y-axis, the height of each instance of M0_PG segment 112 is less than the height of each instance of M0_PG segment 116. Relative to the Y-axis, in some embodiments, the height of each instance of M0_PG segment 112 is approximately the same as (but not greater than) the height of each instance of M0_PG segment 116.

In FIG. 1B, layer MET0 is further organized according to a second grid that includes second reference lines (beta tracks) (not shown) which extend parallel to the X-axis. Instances of M0_rte segments 115 and 116 are aligned correspondingly to the beta tracks. One or more instances of M0_rte segment 115 are aligned to first given one of the beta tracks. and are distributed relative to the X-axis. One or more instances of M0_rte segment 116 are aligned to second given one of the beta tracks. and are distributed relative to the X-axis. However, no instance of M0_rte segment 115 is aligned to the same beta track as an instance of M0_rte segment 116.

Relative to the X-axis, whether a given section of the first given beta track is populated with a given instance of M0_rte segment 115, as well as a determination of a length of the given instance of M0_rte segment 115, depends on the portion of the corresponding second cell region which is under the given section. Relative to the X-axis, similarly, whether a given section of the second given beta track is populated with a given instance of M0_rte segment 116, as well as a determination of a length of the given instance of M0_rte segment 116, depends on the portion of the corresponding second cell region which is under the given section.

In FIG. 1B, each of odd rows RW7 and RW9 has the same layer MET0 architecture as odd rows RW1, RW3 and RW5 of FIG. 1A. Each of even rows RW8 and RW10 has a different layer MET0 architecture than even rows RW2, RW4 and RW6 of FIG. 1A. Each of even rows RW8 and RW10 has two M0_rte-segment-115-specific beta track lines and one M0_rte-segment-116-specific beta track line. Within each of rows RW8 and RW10, M0_rte-segment-116-specific beta track line is between the two M0_rte-segment-115-specific beta track lines. Accordingly, each M0_rte-segment-115-specific beta track line of each of the second cell regions can have (but does not necessarily have) one or more instances of M0_rte segment 115 aligned to each of the two beta tracks for the corresponding row. Also, the M0_rte-segment-115-specific beta track line of each of the second cell regions can have (but does not necessarily have) one or more instances of M0_rte segment 116 aligned to the beta track for the corresponding row.

For simplicity of illustration, relative to the Y-axis, FIG. 1B shows adjacent instances of M0_PG segment 112 as being separated by two instances of M0_rte segment 115 and one instance of M0_rte segment 116. Each instance of M0_rte segment 116 is between two instances of M0_rte segment 115. In some embodiments, each of rows RW7 and RW9 is described as having a ‘four M0_rte segments per row’ architecture. In some embodiments, each of rows RW8 and RW10 is described as having a ‘three M0_rte segments per row’ architecture.

In FIG. 1B, portion 110B represents structures in backside layers. Portion 110B includes: instances of BVD contact 124; instances of BM0_PG rail 118; instances of BM0_PG stub 119; and BM0_LI structures 120(9)-120(14).

In first cell regions 102(9)-102(12), and relative to the Y-axis, instances of BVD contact 124 are substantially overlapped by portions of corresponding instances of BM0_PG rail 118.

BM0_LI structures 120(9)-120(14) are correspondingly in even rows RW8 and RW10. Each of second cell regions 104(8)-104(11) includes at least one BM0_LI structure. As such, BM0_LI structures 120(9)-120(14) are correspondingly in second cell regions 104(8)-104(11). An example of a second cell region having at least two BM0_LI structures is second cell region 104(9) which includes BM0_LI structures 120(10) and 120(11), or the like. Another example of a second cell region having at least two BM0_LI structures is second cell region 104(11) which includes BM0_LI structures 120(13) and 120(14), or the like.

In FIG. 1B, in some embodiments, each of BM0_LI structures 120(9)-120(14) is described as an irregular polygon.

In some embodiments, each of BM0_LI structures 120(9) and 120(12) is described as a concave polygon. In some embodiments, each of BM0_LI structures 120(9) and 120(12) is described as a concave polygon having a Z-shape.

In some embodiments, each of BM0_LI structures 120(10)-120(11) and 120(13)-120(14) is described as a convex polygon. In some embodiments, each of BM0_LI structures 120(10)-120(14) is described as a convex polygon having a shape of a rectangle. In some embodiments, accordingly, each of BM0_LI structures 120(10)-120(14) is described as a as a convex polygon having a shape of a short-rectangle.

Relative to the Y-axis, one or more portions of each of even rows RW8 and RW10 include instances of BM0_PG stub 119. Relative to the Y-axis, some of cell regions 104(8)-104(11) include instances of BM0_PG stub 119, e.g., cell regions 104(8)-104(11). By contrast, in some embodiments, some of the second cell regions (not shown in FIG. 2B) are free from including instances of BM0_PG stub 119.

Relative to the X-axis, each of second cell regions 104(8)-104(11) includes instances of BM0_PG stub 119 to the left and right of corresponding BM0_LI structures 120(9)-120(14). BM0_LI structures 120(9) and 120(12) are located asymmetrically within corresponding second cell regions 104(8) and 104(10) relative to the X-axis, i.e., centers of BM0_LI structures 120(8) and 120(12) are shifted right of centers correspondingly of second cell regions 104(8) and 104(10). Second cell region 104(10) is substantially the same as second cell region 104(8).

Relative to the X-axis, BM0_LI structures 120(10) and 120(13) are substantially completely overlapped correspondingly by BM0_LI structures 120(11) and 120 (140.

BM0_LI structures 120(10) and 120(13) are located asymmetrically within corresponding second cell regions 104(9) and 104(11) relative to the X-axis, i.e., centers of BM0_LI structures 120(10) and 120(13) are shifted right of centers correspondingly of second cell regions 104(9) and 104(11).

BM0_LI structures 120(11) and 120(14) are located substantially symmetrically within corresponding second cell regions 104(9) and 104(11) relative to the X-axis, i.e., centers of BM0_LI structures 120(11) and 120(14) are aligned with centers correspondingly of second cell regions 104(9) and 104(11).

Tall cell region 106(4) is substantially the same as tall cell region 106(3). As such, each of first cell region 102(9) and second cell region 104(11) are substantially the same, and each of second cell regions 104(9) and 104(11) are substantially the same.

FIG. 1C is a layout diagram of a device 100C, in accordance with some embodiments.

Device 100C of FIG. 1C is similar to device 104B of FIG. 1B. For brevity, the discussion will focus on differences of device 100C as compared to device 100B rather than on similarities.

Device 100C of FIG. 1C differs from device 100B of FIG. 1B in terms of layer MET0. Each of devices 100B and 100C includes portion 110B. As such, in FIG. 1C, the layout diagram shows portions 108C and 110B.

Portion 108C of device 100C represents structures in layer MET0, i.e., represents layer MET0 architectures. In portion 108C, even rows RW8 and RW10 are the same as in portion 108B of FIG. 1B. Hence, even rows RW8 and RW10 in portion 108C in FIG. 1C have the same layer MET0 architecture as rows RW8 and RW10 in portion 108 in FIG. 1B.

In FIG. 1C, the odd rows of portion 108C have a different layer MET0 architecture than the odd rows in portion 108 of FIG. 1B. In portion 108C, odd rows RW11 and RW12 have the same layer MET0 architecture as the even rows in portion 108C, i.e., as even rows RW8 and RW10.

Example orientations of each of first cell regions 102(1)-102(12) and each of second cell regions 104(1)-104(11) have been shown correspondingly in FIGS. 1A-1C relative to the X-axis and the Y-axis. In general, in some embodiments, one or more of various first cell regions and/or one or more of various second cell regions are insertable into layout diagrams having different orientations with respect to the X-axis and/or with respect to the Y-axis. For example, the BUFFD4 cell region having front side 342F of FIG. 3C and back side 342R of FIG. 3D is an example of second cell region 104(1) or 104(7) of FIG. 1A albeit rotated 180 degrees (180°) about the X-axis.

FIGS. 2A-2B are corresponding cross-sectional views 225A-225B of a device, in accordance with some embodiments. The device corresponding to cross-sections 225A-225B of FIGS. 2A-2B is an example of device that includes cell region 104(4) of FIG. 1A.

Cross-section 225A of FIG. 2A corresponds to section IIA-IIA′ of FIG. 1A. Cross-section 225B of FIG. 2B corresponds to section IIB-IIB′ of FIG. 1A. In FIGS. 2A-2B, an orthogonal Cartesian coordinate system is assumed in which a first direction is parallel to the X-axis, a second direction is parallel to the Y-axis and a third direction is parallel to the Z-axis. For simplicity of illustration, not all components in each of FIGS. 2A-2B are called out with a corresponding reference number. The extensions correspondingly of cross-sections 225A-225B relative to the Y-axis is truncated by instances of break line-pair 237.

Cross-sections 225A-225B follow a similar numbering scheme to that of the layout diagrams of FIG. 1A. Though some components correspond, some components also differ. To help identify components which correspond but nevertheless have differences, the numbering convention uses 2-series numbers for cross-sections 225-225B while FIG. 1A uses 1-series numbers. For example, instances of M0_rte segment 214 in each of FIGS. 2A-2B correspond to instances of M0_rte segment 114 in FIG. 1A. For brevity, the discussion will focus more on differences between FIGS. 2A-2B and FIG. 1A than on similarities.

In FIGS. 2A-2B, a reference line 226 extends parallel to the Y-axis. Reference line 226 substantially bisects an active regions (AR) layer 227 relative to the Z-axis. An area above reference line 226 is referred to as a front side 211F. An area below reference line 226 is referred to as a back side (or rear side) 211R. Layer MET0 208 is above reference line 226 and thus is on front side 211F of each of cross-sections 225A-225B. Layer BMET0 209 is below reference line 226 and thus is on back side 211R of each of cross-sections 225A-225B. Field-effect transistor (FET) components (discussed below) are in an FET-components layer 228. Relative to the Z-axis, FET-components layer 228 is between layer MET0 208 and layer BMET0 layer 209.

In FIG. 2A, ARs layer 227 includes source/drain (S/D) regions 229D1(1), 229D1(2), 229D2(1) and 229D(2) that have been formed in corresponding active regions (FIG. 2B). In some embodiments, D1 is an alphanumeric text string that is intended to connote that S/D regions 229D1(1) and 229D1(2) are formed in corresponding active regions that have been doped with a first type of dopant, e.g., an N-type dopant used for negative-channel metal-oxide semiconductor (NMOS) transistor technologies. In some embodiments, D2 is an alphanumeric text string that is intended to connote that S/D regions 229D2(1) and 229D2(2) are formed in corresponding active regions that have been doped with a second type of dopant, e.g., a P-type dopant used for positive-channel metal-oxide semiconductor (PMOS) transistor technologies. In some embodiments, the first dopant type is an N-type dopant and the second dopant type is a P-type dopant. In some embodiments, S/D regions 229D1(1) and 229D1(2) correspondingly are an epitaxially grown semiconductor, e.g., silicon, having an N-type dopant. In some embodiments, S/D regions 229D2(1) and 229D2(2) correspondingly are an epitaxially grown semiconductor, e.g., silicon, having a P-type dopant.

In FIG. 2A, layer MET0 208 includes instances of M0_PG segment 212 and instances of M0_rte segment 214. FET-components layer 228 includes metal-to-S/D-region (MD) contacts 230(1) and 230(2) that are formed partially around corresponding S/D regions 229D2(1) and 229D1(2), and an instance of a via-to-MD (VD) contact 224. MD contact 230(2) is coupled to an instance of M0_PG segment 212 by an instance of VD contact.

At least some embodiments facilitate removing instances of dummy MD contacts that are not functional and thus are not necessary, which has a beneficial effect of reducing parasitic capacitance. An instance of dummy MD contact having been removed is indicated by instances of a phantom (dashed line) box 231. In some embodiments, instances of phantom box 231 are referred to as ghost-intersections 231 because otherwise an MD contact would intersect an active region at the ghost-intersection location. As compared to counterpart cell regions according to another approach, in some embodiments, cell regions show an increased count of ghost-intersections, cnt_GH, in a range of 2≤cnt_GH≤5. In other words, as compared to counterpart cell regions according to another approach, in some embodiments, cell regions show a decreased count of MD-intersections, cnt_MD, in a range of 2≤cnt_MD≤5.

In FIG. 2A, layer BMET0 209 includes BM0_PG rails 218(1) and 218(2) and a BM0_LI structure 220(5). BM0_LI structure 220(5) corresponds to BM0_LI structure 120(5). Each of BM0_PG rails 218(1) and 218(2) is wider than each instance of M0_PG segment 212. At least a portion of each of BM0_LI structures 120(1)-120(2), 120(4)-120(5), 120(7)-120(9) and 120(12) is wider/taller than each of BM0_PG rails 218(1) and 218(2) relative to the Y-axis.

FET-components layer 228 further includes instances of BVD contact 224. Opposite ends/sides of BM0_LI structure 220(5) are coupled correspondingly to S/D regions 229D1(1) and 229D2(2) by instances of BVD contact 224. BM0_PG rail 218(2) is coupled to S/D region 229D2(2) by an instance of BVD contact 224.

In FIG. 2A, S/D regions 229D1(1) and 229D2(2), BM0_LI structure 220(5), instances of BVD contact 224, instances of M0_rte segment 214 and portions of instances of M0_PG segment 212 are in row RW4, and more particularly are in second cell region 204(4), where the latter is an SDFQD1 cell region. In FIG. 2A, S/D region 229D1(2), BM0_PG rail 218(2), an instance of BVD contact 224, MD contact 230(2), an instance VD contact, an instance of M0_rte segment 214 and a portion of an instance of M0_PG segment 212 are in row RW5, and more particularly are in first cell region 202(7). In FIG. 2A, the group including S/D region 229D2(1), BM0_PG rail 218(1), MD contact 230(1), an instance of M0_rte segment 214 and a portion of an instance of M0_PG segment 212 is: in row RW3; and, more particularly, is between first cell regions corresponding to first cell regions 102(4) and 102(5) in FIG. 1A relative to the X-axis.

In FIG. 2B, layer BMET0 209 includes BM0_PG rails 218(1) and 218(2) and a BM0_LI structure 220(5). ARs layer 227 includes active region (AR) structures 235D1(1), 235D1(2), 235D2(1) and 235D2(2). Each of AR structures 235D1(1) and 235D1(2) includes instances of nanosheets D1. Each of AR structures 235D2(1) and 235D2(2) includes instances of nanosheets D2. In some embodiments, D1 is an alphanumeric text string that is intended to connote that nanosheets D1 are formed of a semiconductor, e.g., silicon, that has been doped with a first type of dopant, e.g., an N-type dopant, and correspondingly that AR structures 235D1(1) and 235D1(2) are N-type AR structures. In some embodiments, D2 is an alphanumeric text string that is intended to connote that nanosheets D2 are formed of a semiconductor, e.g., silicon, that has been doped with a second type of dopant, e.g., a P-type dopant, and correspondingly that AR structures 235D2(1) and 235D2(2) are P-type AR structures. In some embodiments, the first dopant type is an N-type dopant and the second dopant type is a P-type dopant.

In FIG. 2B, FET-components layer 228 further includes: gates 233(1)-233(3) that are formed partially around corresponding AR structures 235D2(1), 235D1(1) & 235D2(2), and 235D1(2); and an instance of a via-to-MM (VG) contact. AR structures 235D(1) and 235D(2) are coupled together by gate 233(2). gate 233(3) is coupled to an instance of M0_rte segment 214 by an instance of VG contact.

FET-components layer 228 further includes an instance of BVG contact 222. BM0_LI structure 220(5) is coupled to AR structure 235D(1) by an instance of BVG contact 222.

In FIG. 2B, AR structures 235D(1) and 235D(2), gate 233(2), BM0_LI structure 220(5), an instance of BVG contact 222, instances of M0_rte segment 214 and portions of instances of M0_PG segment 212 are in row RW4, and more particularly are in second cell region 204(4), where the latter is an SDFQD1 cell region.

In FIG. 2B, AR structure 235D1(2), gate 233(3), BM0_PG rail 218(2), an instance BVG contact 222, an instance of M0_rte segment 214 and a portion of an instance of M0_PG segment 212 are in row RW5, and more particularly are in first cell region 202(7).

In FIG. 2B, the group including AR structure 235D2(1), gate 233(1), BM0_PG rail 218(1), an instance of M0_rte segment 214 and a portion of an instance of M0_PG segment 212 is: in row RW3; and, more particularly, is between first cell regions corresponding to first cell regions 102(4) and 102(5) in FIG. 1A relative to the X-axis.

FIG. 2C will be discussed below albeit after the discussion of FIGS. 3E-3F.

FIGS. 3A-3B are corresponding layout diagrams 340F and 340R of a BUFFD4 cell region, in accordance with some embodiments.

Layout diagrams 340F and 340F correspondingly represent front and back sides of the BUFFD4 cell region. The BUFFD4 Cell region having front 340F and back 340R sides is an example of first cell regions 102(3), 102(5) or 102(6) of FIG. 1A, or the like. Each of FIGS. 3A-3B includes an odd row RW33. FIG. 3A additional includes portions of even rows RW32 and RW34 correspondingly on upper and lower zones of row RW33. The extension correspondingly of front 340F and back 340R side relative to the Y-axis is truncated by instances of break line-pair 237.

FIG. 3A includes: active regions; gates; MD contacts; VD contacts; VD rail (VDR) contacts; M0_rte segments; M0_dummy segments; and M0_PG segments. FIG. 3B includes: BM0_PG stubs; BVD contacts; active regions; and gates. VDR contacts facilitate coupling, e.g., first and second instances of MD contacts.

Relative to the X-axis, adjacent ones of gate lines are separated by a uniform distance. In some embodiments, the uniform distance is a multiple of a given unit of distance-measure. In some embodiments, the value of the multiple is one such that the uniform distance is one instance of the given unit of distance-measure. Relative to the X-axis, the BUFFD4 cell region having front 340F and back 340R sides has a width of 5 CPP.

In some embodiments, the unit of distance-measure is 1.0 CPP. In some embodiments, CCP is an acronym for contacted poly pitch. A value for CPP is determined, e.g., by the design rules and scale of the corresponding semiconductor process technology node. Here, the word ‘poly’ in the term CPP does not necessarily imply that the gate lines in semiconductor devices based correspondingly on FIGS. 3A-3B are to be formed of polysilicon but instead represents a historical convenience—gate structures in ICs manufactured according to one or more predecessor semiconductor process technology nodes often were formed of polysilicon which lead to the term ‘poly’ being used colloquially to mean ‘gate line.’

In some embodiments, the gate lines which align correspondingly with left and right boundaries of the BUFFD4 cell region are replaced by corresponding isolation dummy gates (IDGs). (discussed below). More generally, in other layout diagrams disclosed therein, e.g., FIGS. 3C-3F, 4A-4F, 5B-5C, or the like, in some embodiments, the gate lines which align correspondingly with left and right boundaries of the corresponding cell region are replaced correspondingly by IDGs.

In some embodiments, an IDG is a dielectric structure that includes one or more dielectric materials and functions as an electrical isolation structure. Accordingly, an IDG is not a structure that is electrically conductive and thus does not function, e.g., as an active gate of a transistor. An IDG includes one or more dielectric materials and functions as an electrical isolation structure. In some embodiments, an IDG is based on a gate as a precursor. In some embodiments, a method of forming an IDG includes: forming a gate; sacrificing/removing (e.g., etching) the gate to form a trench at least partially around the corresponding portion of the active region; (optionally) removing a portion or all of the corresponding active region that previously had been partially surrounded by the gate to deepen the trench and thereby partially or completely divide the corresponding active region from extending beyond/outside the corresponding left or right side of cell region relative to the X-axis; and then filling the trench with one or more dielectric materials such that the physical dimensions of the resultant electrical isolation structure, i.e., the IDG, are similar to the dimensions of the gate which was sacrificed. In some embodiments, an IDG is a dielectric feature that includes one or more dielectric materials (e.g., oxide, nitride, oxynitride, or other suitable materials), and functions as an isolation feature. In some embodiments, an IDG is a type of continuous polysilicon on oxide diffusion (OD) edge structure and is referred to as a type of CPODE structure.

FIGS. 3C-3D are corresponding layout diagrams 342F and 342R of a BUFFD4 cell region, in accordance with some embodiments.

Layout diagrams 342F and 342R correspondingly represent front and back sides of the BUFFD4 cell region. The BUFFD4 cell region having front side 342F and back side 342R is an example of second cell region 104(1) or 104(7) of FIG. 1A albeit with a different orientation, i.e., rotated 180 degrees (180°) about the X-axis, or the like. Each of FIGS. 3C-3D includes: an even row RW36; and portions of odd rows RW35 and RW37 correspondingly abutting upper and lower boundaries of row RW32. Relative to the X-axis, the BUFFD4 cell region having front side 342F and back side 342R has a width of 6 CPP.

In terms of included types of components/structures, FIG. 3C is similar to FIG. 3A, however FIG. 3C further includes: V0 contacts in layer VA0; and M1_rte segments in layer MET1. In terms of included types of components/structures, FIG. 3D is similar to FIG. 3B, however FIG. 3D further includes a BM0_LI structure 320(1) and an instance of BM0_PG_stub 319. Relative to the Y-axis, a bottom zone of row RW35 and a top zone of row RW37 includes BM0_PG rails 318.

The upper zone of back side 342R includes a BM0_PG stub that extends from approximately the middle of back side 342R to a right side boundary of back side 342R. The BM0_PG stub in back side 342R is coupled to the BM0_PG rail in row RW35. The ability to couple the BM0_PG stub in back side 342R of even row RW36 to the BM0_PG rail in odd row RW35 is a benefit of the arrangement of FIGS. 3C-3D, i.e., is a benefit of the architecture of alternating row-arrangements disclosed herein.

In FIG. 3C, M0_rte segments are organized according to four alpha tracks (not shown). However, in FIG. 3C, M0_rte segments are aligned to two of the four alpha tracks. In FIG. 3C, two of the alpha tracks are free from having an M0_rte segment aligned thereto.

In general, in some embodiments, alpha track usage in second cell regions, cnt_α, is reduced as compared to cell regions according to another approach that represent corresponding counterparts to the second cell regions. In some embodiments, alpha track usage in second cell regions is reduced in a range, 1≤cnt_α≤2, as compared to the corresponding counterpart cell regions.

As a counterpart to the BUFFD4 cell region having front side 342F and back side 342R, a BUFFD4 cell region (not shown) according to another approach (A) does not include a BM0_LI structure, and (B) each of the four alpha tracks thereof has one or more M0_rte segments aligned thereto. As such, the counterpart BUFFD4 cell region according to the other approach suffers increased M0 routing congestion and increased circumstances for parasitic capacitances. By contrast, by using BM0_LI structure 320(1) to reduce M0 routability congestion, the BUFFD4 cell region having front side 342F and back side 342R reduces alpha track usage by 50% as compared to the counterpart BUFFD4 cell region according to the other approach, which reduces circumstances for parasitic capacitances as compared to the counterpart BUFFD4 cell region according to the other approach.

FIGS. 3E-3F are corresponding layout diagrams 344F and 344R of a BUFFD4 cell region, in accordance with some embodiments.

In FIGS. 3E-3F, section line IIC-IIC′ extends parallel to the Y-axis. Section line IIC-IIC′ corresponds to the cross-sectional view 225C of FIG. 2C.

Layout diagrams 344F and 344F correspondingly represent front and back sides of the BUFFD4 cell region. The BUFFD4 cell region having front 342F side and back side 342R is an example of a second cell region of FIG. 1A. Each of FIGS. 3C-3D includes: an even row RW40; and portions of odd rows RW39 and RW41 correspondingly abutting upper and lower boundaries of row RW40. Relative to the X-axis, the BUFFD4 cell region having front side 344F and back side 344R has a width of 6 CPP.

In terms of included types of components/structures, FIG. 3E is similar to FIG. 3C. In terms of included types of components/structures, FIG. 3F is similar to FIG. 3D, however FIG. 3F further includes BVD rail (BVDR) contact 323. Relative to the Y-axis, a bottom zone of row RW39 and a top zone of row RW41 includes BM0_PG rails 318. BVDR contacts 323 facilitate coupling, e.g., between first and second instances of S/D regions (FIG. 2B).

In FIG. 3E, M0_rte segments are organized according to four alpha tracks (not shown). However, in FIG. 3E, M0_rte segments are aligned to three of the four alpha tracks. In FIG. 3E, one of the alpha tracks is free from having an M0_rte segment aligned thereto.

As a counterpart to the BUFFD4 cell region having front side 344F and back side 344R, a BUFFD4 cell region (not shown) according to another approach (A) does not include a BVD rail (BVDR) contact, and (B) each of the four alpha tracks thereof has one or more M0_rte segments aligned thereto. As such, the counterpart BUFFD4 cell region according to the other approach suffers increased M0 routing congestion and increased circumstances for parasitic capacitances. By contrast, by using BVD rail (BVDR) contact 323 to reduce M0 routability congestion, the BUFFD4 cell region having front side 344F and back side 344R reduces alpha track usage by 25% as compared to the counterpart BUFFD4 cell region according to the other approach, which reduces circumstances for parasitic capacitances as compared to the counterpart BUFFD4 cell region according to the other approach.

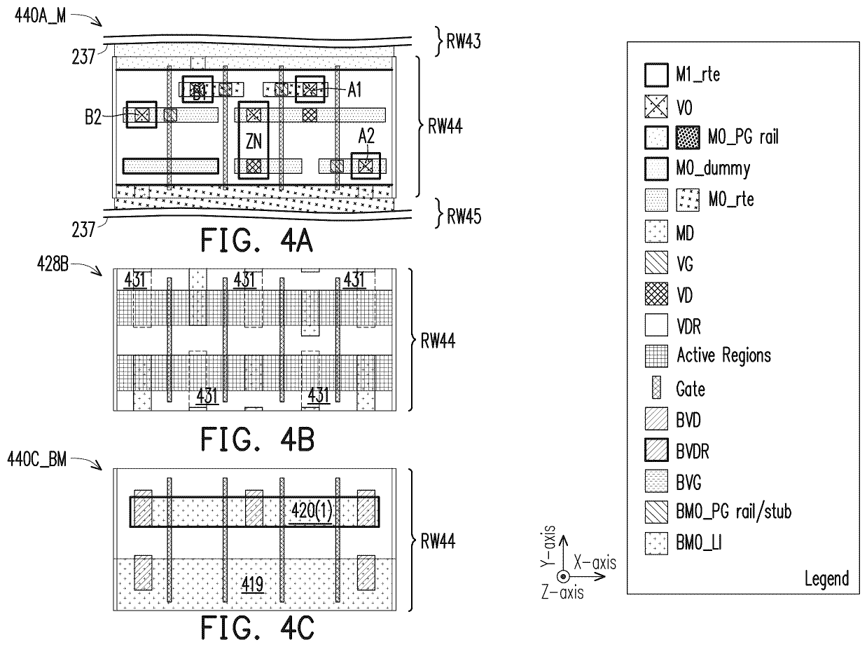

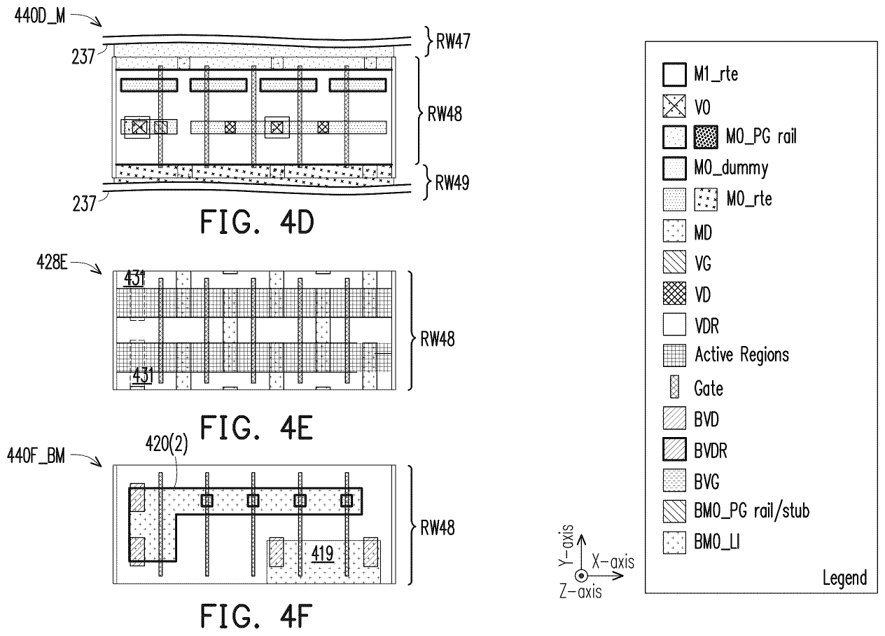

Before discussing FIGS. 4A-4C, the discussion will revert to FIG. 2C, which corresponds to FIGS. 3C-3D.

FIG. 2C is a cross-sectional view 225C of a device, in accordance with some embodiments. The device corresponding to cross-section 225C of FIG. 2C is an example of device based on front side 342F and back side 342R of corresponding FIGS. 3E-3F.

Cross-section 225C of FIG. 2C corresponds to section IIC-IIC′ of FIGS. 3E-3F. In FIG. 2C, an orthogonal Cartesian coordinate system is assumed in which a first direction is parallel to the X-axis, a second direction is parallel to the Y-axis and a third direction is parallel to the Z-axis. The extension correspondingly of cross-section 225C relative to the Y-axis is truncated by instances of break line-pair 237.

FIG. 2C includes: BM0_PG rails 218(3) and 218(4); BM0_LI structure 220(2); BDVR contact 223; SD regions 229D1(3) and 229D2(3); instances of M0_PG segment 212; and instances of MG_rte segment 214.

FIGS. 4A-4C are corresponding layout diagrams 440A_M, 428B and 440C_BM of an AOI22D1 cell region, in accordance with some embodiments.

Layout diagram 440A_M represents layer MET0, layer VIA0 and layer MET1 of the corresponding AOI22D1 cell region. Layout diagram 428B represents the FET-components layer of the corresponding AOI22D1 cell region. Layout diagram 440C_BM represents layer BMET0 of the corresponding AOI22D1 cell region.

The AOI22D1 cell region having layout diagrams 440A_M, 428B and 44C_BM is an example of second cell regions 104(3) or 104(5) of FIG. 1A, or the like. Each of FIGS. 4A-4C includes an even row RW44. FIG. 4A additionally includes portions of odd rows RW43 and RW45 correspondingly abutting upper and lower boundaries of row RW44. The extensions correspondingly of layout diagram 440A_M relative to the Y-axis is truncated by instances of break line-pair 237. The AOI22D1 cell region having layout diagrams 440A_M, 428B and 44C_BM has a width of 5 CPP.

FIG. 4A includes: VD contacts; M0_rte segments; M0_dummy segments; M0_PG segments. gates; V0 contacts; M1_rte segments; and MD contacts (albeit showing only portions thereof under the M0_PG segments (for simplicity of illustration). FIG. 4B includes: active regions; gates; MD contacts; and ghost-intersections 431. FIG. 4C includes: BVD contacts; gates; an BM0_PG stub 419; and a BM0_LI structure 420(1).

BM0_PG stub 419 is coupled to a BM0_PG rail (not shown) in row RW45. The ability to couple BM0_PG stub 419 of even row RW44 to the BM0_PG rail (not shown) in odd row RW45 is a benefit of the arrangement of FIGS. 4A-4C, i.e., is a benefit of the architecture of alternating row-arrangements disclosed herein.

A counterpart AOI22D1 cell region (not shown) according to another approach has two ghost-intersections where MD contacts would otherwise be over the lower active region relative to the Y-axis. In contrast, the AOI22D1 cell region having layout diagrams 440A_M, 428B and 440C_BM has an additional three ghost-intersections 431 where MD contacts would otherwise be over the upper active region relative to the Y-axis, i.e., an improvement in the number of ghost-intersections by about 37.5%.

In FIG. 4B, ghost-intersections 431 are the result of at least some embodiments facilitating the removal of MD contacts that are not functional and thus are not necessary. As such, ghost-intersections 431 correspondingly represent benefits resulting from having reduced parasitic capacitance by correspondingly having removed MD contacts that are not functional and thus are not necessary.

In FIG. 4A, M0_rte segments are organized according to four alpha tracks (not shown). However, in FIG. 4A, M0_rte segments are aligned to three of the four alpha tracks. In FIG. 4A, one of the alpha tracks is free from having an M0_rte segment aligned thereto. The counterpart AOI22D1 cell region (not shown) according to another approach (A) does not include a BM0_LI structure, and (B) each of the four alpha tracks thereof has one or more M0_rte segments aligned thereto. As such, the counterpart AOI22D1 cell region according to the other approach suffers increased M0 routing congestion and increased circumstances for parasitic capacitances. By contrast, by using BM0_LI structure 420(1) to reduce M0 routability congestion, the AOI22D1 cell region having layout diagrams 440A_M, 428B and 440C_BM reduces alpha track usage by 25% as compared to the countpart AOI22D1 cell region according to the other approach, which reduces circumstances for parasitic capacitances as compared to the counterpart AOI22D1 cell region according to the other approach.

FIGS. 4D-4F are corresponding layout diagrams 440D_M, 428E and 440F_BM of a BUFFD4 cell region, in accordance with some embodiments.

Layout diagram 440A_M represents layer MET0, layer VIA0 and layer MET1 of the corresponding BUFFD4 cell region. Layout diagram 428B represents the FET-components layer of the corresponding BUFFD4 cell region. Layout diagram 440C_BM represents layer BMET0 of the corresponding BUFFD4 cell region.

The BUFFD4 cell region having layout diagrams 440D_M, 428E and 440F_BM is an example of is an example of second cell regions 104(1) or 104(7) of FIG. 1A, or the like. Each of FIGS. 4D-4F includes an even row RW48. FIG. 4D additionally includes portions of odd rows RW47 and RW479 correspondingly abutting upper and lower boundaries of row RW48. The extensions correspondingly of layout diagram 440A_M relative to the Y-axis is truncated by instances of break line-pair 237. The BUFFD4 cell region having layout diagrams 440D_M, 428E and 44F_BM has a width of 6 CPP.

FIG. 4D includes: VD contacts; M0_rte segments; M0_dummy segments; M0_PG segments, gates; V0 contacts; M1_rte segments; and MD contacts (albeit showing only portions thereof under the M0_PG segments (for simplicity of illustration). FIG. 4E includes: active regions; gates; MD contacts; and ghost-intersections 431. FIG. 4F includes: BVD contacts; gates; an BM0_PG stub 419; and a BM0_LI structure 420(2).

BM0_PG stub 419 is coupled to a BM0_PG rail (not shown) in row RW49. The ability to couple BM0_PG stub 419 of even row RW48 to the BM0_PG rail (not shown) in odd row RW49 is a benefit of the arrangement of FIGS. 4D-4F, i.e., is a benefit of the architecture of alternating row-arrangements disclosed herein.

In FIG. 4D, M0_rte segments are organized according to four alpha tracks (not shown). However, in FIG. 4D, M0_rte segments are aligned to two of the four alpha tracks. That is, two of the alpha tracks are free from having an M0_rte segment aligned thereto in FIG. 4D.

A counterpart BUFFD4 cell region (not shown) according to another approach does not include a BM0_LI structure such that each of the four alpha tracks of the counterpart BUFFD4 cell region has one or more M0_rte segments aligned thereto. As such, the counterpart BUFFD4 cell region according to the other approach suffers increased M0 routing congestion and an increased number of circumstances that produce parasitic capacitances. In contrast, by using BM0_LI structure 420(2) to reduce M0 routability congestion, the BUFFD4 cell region having layout diagrams 440D_M, 428E and 440F_BM also reduces the number of circumstances that produce parasitic capacitances as compared to the counterpart BUFFD4 cell region according to the other approach.

A counterpart BUFFD4 cell region (not shown) according to another approach has zero ghost-intersections where MD contacts would otherwise be over the upper or lower active regions relative to the Y-axis. In contrast, the BUFFD4 cell region having layout diagrams 440D_M, 428E and 440F_BM has an additional two ghost-intersections 431 where MD contacts would otherwise be over the upper active region relative to the Y-axis, i.e., an improvement in the number of ghost-intersections by about 16.7%

In FIG. 4E, ghost-intersections 431 are the result of at least some embodiments facilitating the removal of MD contacts that are not functional and thus are not necessary. As such, ghost-intersections 431 correspondingly represent benefits resulting from having reduced parasitic capacitance by correspondingly having removed MD contacts that are not functional and thus are not necessary.

In FIG. 4D, M0_rte segments are organized according to four alpha tracks (not shown). However, in FIG. 4D, M0_rte segments are aligned to two of the four alpha tracks. In FIG. 4D, two of the alpha tracks are free from having an M0_rte segment aligned thereto. The counterpart BUFFD4 cell region (not shown) according to another approach (A) does not include a BM0_LI structure, and (B) each of the four alpha tracks thereof has one or more M0_rte segments aligned thereto. As such, the counterpart BUFFD4 cell region according to the other approach suffers increased M0 routing congestion and increased circumstances for parasitic capacitances. By contrast, by using BM0_LI structure 420(2) to reduce M0 routability congestion, the BUFFD4 cell region having layout diagrams 440D_M, 428E and 440F_BM reduces alpha track usage by 50% as compared to the counterpart BUFFD4 cell region according to the other approach, which reduces circumstances for parasitic capacitances as compared to the counterpart BUFFD4 cell region according to the other approach.

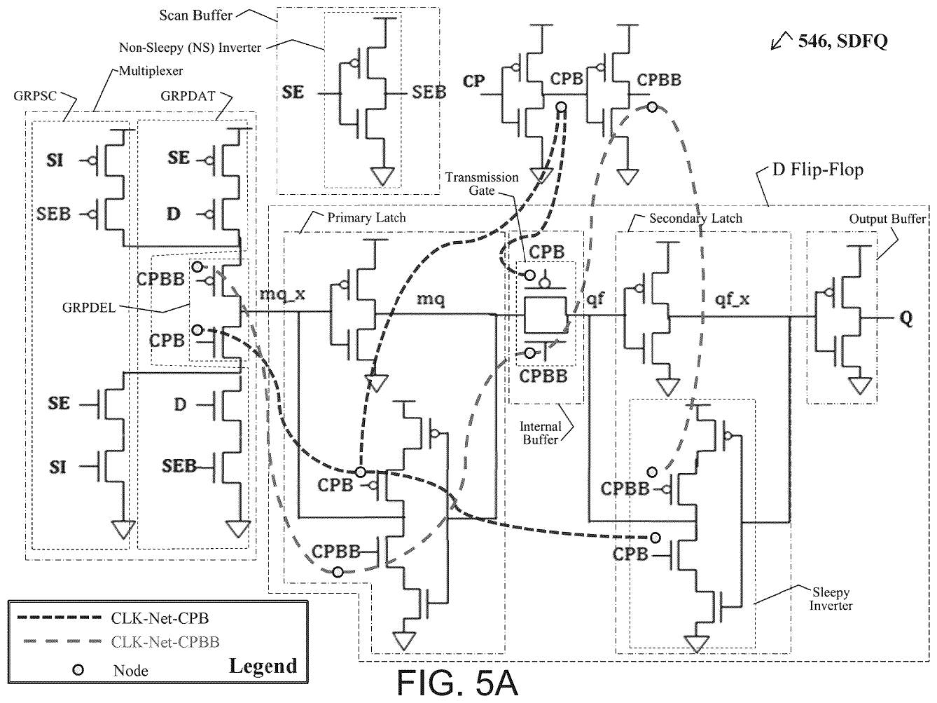

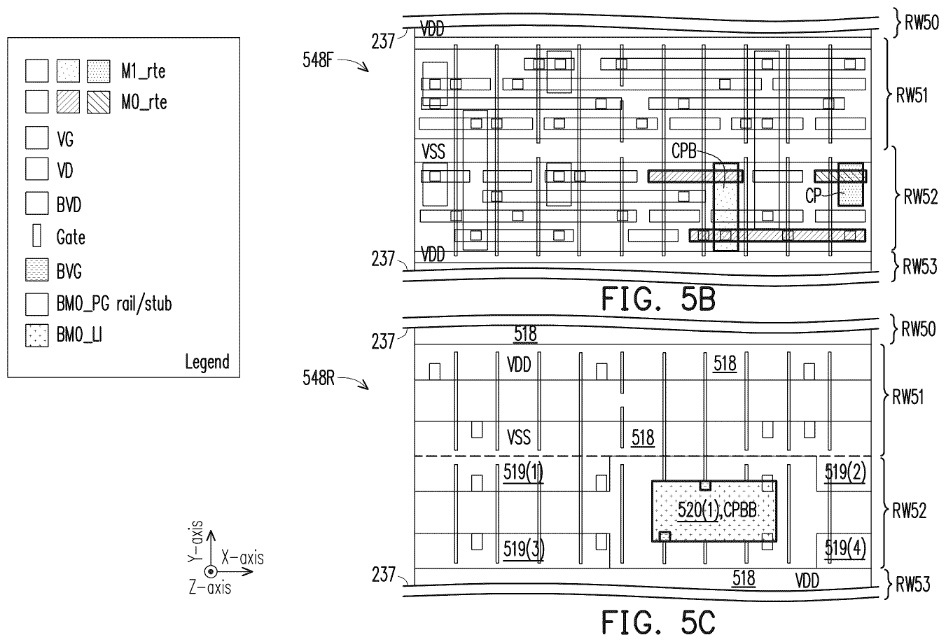

FIG. 5A is a schematic circuit diagram of an SDFQ 546, in accordance with some embodiments.

Examples of SDFQ cell regions for which SDFQ 546 is a representative schematic circuit diagram include SDFQD1 cell regions 106(1) and 106(2) of FIG. 1A, 106(3) and 106(4) of FIGS. 1B-1C, or the like.

SDFQ 546 is a transmission-gate-based design (discussed below). SDFQ 546 is an edge-triggered arrangement that is triggered on a rising edge (positive edge) of a clock signal. Variations of SDFQ 546 are triggered on the falling edge (negative edge) of the clock signal. Other variations of SDFQ 546 are double edge-triggered, i.e., are triggered by both the rising edge (positive edge) and falling edge (negative edge) of the clock signal.

SDFQ 546 includes a multiplexer, a D flip-flop, a scan buffer and a clock buffer. SDFQ 546 includes field-effect transistors (FETs), and more particularly, positive-channel metal oxide semiconductor (PMOS) FETs (PFETs) and negative-channel metal oxide semiconductor (NMOS) FETs (NFETs). Some of the FETs of SDFQ 546 are arranged to function together as sleepy inverters (discussed below). Some of the FETs of SDFQ 546 are arranged to function together as non-sleepy (NS) inverters (discussed below).

In FIG. 5A, the clock buffer includes first and second NS inverters coupled in series. The input node of the first NS inverter is configured to receive a clock signal CP. The output node of the first NS inverter has a clock signal CPB which represents the inversion of clock signal CP. The output node of the first NS inverter is the input node of the second NS inverter. The input node of the second NS inverter is configured to receive clock signal CPB. The output node of the second NS inverter has a clock signal CPBB which represents the inversion of clock signal CPB.

Various nodes in SDFQ 546 are configured to receive clock signal CP; together, such nodes represent a clock network for CP (CLK-net-CP). Various nodes in SDFQ 546 are configured to receive clock signal CPB; together, such nodes represent a clock network for CPB (CLK-net-CPB). Various nodes in SDFQ 546 are configured to receive clock signal CPBB; together, such nodes represent a clock network for CPBB (CLK-net-CPBB).

In FIG. 5A, the scan buffer receives a Scan/Test Enable (SE) signal that selects between normal, i.e., non-scan/test, operation relative to a data signal D or scan/test operation relative to a Scan Input (SI) signal. Scan buffer includes a non-sleepy (NS) inverter. An NS inverter is a counterpart to a sleepy inverter (discussed below).

In FIG. 5A, the multiplexer includes a group of data transistors GRPDAT (data group GRPDAT), a group of scan transistors GRPSC (scan group GRPSC), and a group of delay transistors GRPDEL (delay group GRPDEL). Data group GRPDAT is used for selecting the data input signal D. Scan group GRPSC is used for selecting the scan input signal SI. Delay group GRPDEL is used for delaying the propagation of the selected input, namely either SI or D, through the multiplexer. The output node of the multiplexer has a signal mq_x.

In FIG. 5A, the D flip-flop includes a primary latch, an internal buffer, a secondary latch and an output buffer 242. The primary latch includes an NS inverter and a sleepy inverter. The input node of the primary latch is configured to receive the signal mq_z from the multiplexer, and the output node has a signal mq. Signal mq represents the inversion of signal mq_x. The sleepy inverter can be put into a sleep mode of operation due to the inclusion of a PFET configured to receive clock signal CPB and an NFET configured to receive clock signal CPBB. By contrast, the NS inverter lacks a PFET configured to receive clock signal CPB and an NFET configured to receive clock signal CPBB such that the NS-inverter lacks a sleep mode of operation; accordi″gly, the NS inverter is described as a non-sleepy (NS) inverter. the sleepy inverter feeds-back an inverted version of signal mq to the input of the NS-inverter, and thus to the input of the primary latch.

In FIG. 5A, the internal buffer includes a transmission gate. Describing SDFQ 546 as a transmission-gate-based design is informed by the inclusion of the transmission gate in SDFQ 546. The input node of the internal buffer, i.e., of the transmission gate, is configured to receive the signal mq from the primary latch. An output node of the internal buffer, i.e., of the transmission gate, has a signal qf.

In the D flip-flop, the secondary latch includes an NS inverter and a sleepy inverter. The input node of the secondary latch is configured to receive the signal qf from the internal buffer, and the output node has a signal qf_x. Signal qf_z represents the inversion of signal qf.

In the D flip-flop, the output buffer includes an NS inverter. The input node of the output buffer is configured to receive signal qf_x, and the output node has a signal Q. The output node of the output buffer represents the output node of the D flip-flop, and thus also represents the output node of SDFQ 546. Signal Q represents the inversion of signal qf_x.

In FIG. 5A, the D flip-flop is a transmission-gate-based design because the internal buffer thereof includes a transmission gate. In some embodiments, the D flip-flop is a stack-gate-based design (not shown). More particularly, whereas the internal buffer of FIG. 5A includes the transmission gate, a stack-gate-based version of the D flip-flop includes a version of the internal buffer which is stack-gate-based. In some embodiments, the stack-gate-based version of the internal buffer includes a sleepy inverter (not shown) in place of the transmission gate, where a sleepy inverter is an example of a stack-gate-based device. Like the transmission gate, the output of the alternative sleepy inverter is coupled to the input of the secondary latch. In contrast to the transmission gate, the input of the alternative sleepy inverter in the stack-gate-based device is not connected to the output node of the primary latch but instead is connected to the output node of the multiplexer.

FIGS. 5B-5C are corresponding layout diagrams 548F and 548R of BUFFD4 cell region, in accordance with some embodiments.

Layout diagrams 548F and 548R correspondingly represent front and back sides of the SDFQD1 cell region. The SDFQD1 cell region having front side 548F and back side 548R is an example of SDFQD1 cell regions 106(1) or 106(2) of FIG. 1A, or the like. Each of FIGS. 5B-5C includes: a portion of an even row RW50, an odd row RW51, an even row RW52, and a portion of an odd row RW53. Relative to the X-axis, the BUFFD4 cell region having front side 344F and back side 344R has a width of 11 CPP. The extensions correspondingly of each of layout diagrams 548F and 548R relative to the Y-axis are truncated by instances of break line-pair 237.

FIG. 5B includes: VD contacts; M0_rte segments; M0_dummy segments; M0_PG segments, gates; V0 contacts; and M1_rte segments. FIG. 5C includes: BVD contacts; BVG contacts; gates; BM0_PG rails 518; BM0_PG stubs 419; and a BM0_LI structure 520(1).

BM0_PG stubs 519(1) and 519(2) are coupled to BM0_PG rail 518 in the lower zone of row RW51. BM0_PG stubs 519(3) and 519(4) are coupled to BM0_PG rail 518 in the upper zone of row RW53. The ability to couple BM0_PG stubs 519(1)-519(4) to corresponding ones of BM0_PG rails 518 is a benefit of the arrangement of FIGS. 5B-5C, i.e., is a benefit of the architecture of alternating row-arrangements disclosed herein.

In FIG. 5A, CLK-net-CP and CLK-CPB are routed using M0_rte segments and M1_rte segments. In FIG. 5B, CLK-net-CPBB is routed using BM0_LI structure 520(1). A counterpart SDFQ cell region (not shown) according to another approach (A) does not include a BM0_LI structure and (B) routes each of CLK-net-CP, CLK-net-CPB and CLK-net-CPBB using M0_rte segments and M1_rte segments. The presence of all three clock networks on the front side of the counterpart SDFQ cell region according to the other approach suffers increased M0 routing congestion and thus increased circumstances for parasitic capacitances, resulting in slower speeds of operation and increased power consumption. In contrast, the SDFQD1 cell region having front side 548F and back side 548R reduces M0 routing congestion and thus reduces circumstances for parasitic capacitances by moving CLK-net-CPBB to back side 548R using BM0_LI structure 520(1), as compared to the counterpart SDFQ cell region according to the other approach. Accordingly, the SDFQD1 cell region having front side 548F and back side 548R beneficially exhibits faster speeds of operation and reduced power consumption as compared to the counterpart SDFQ cell region according to the other approach.

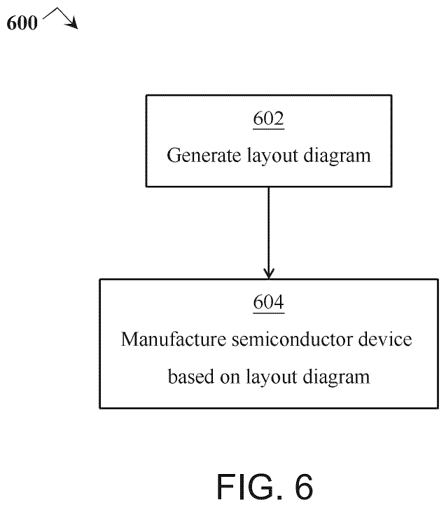

FIG. 6 is a flowchart 600 of a method of manufacturing a memory device, in accordance with some embodiments.

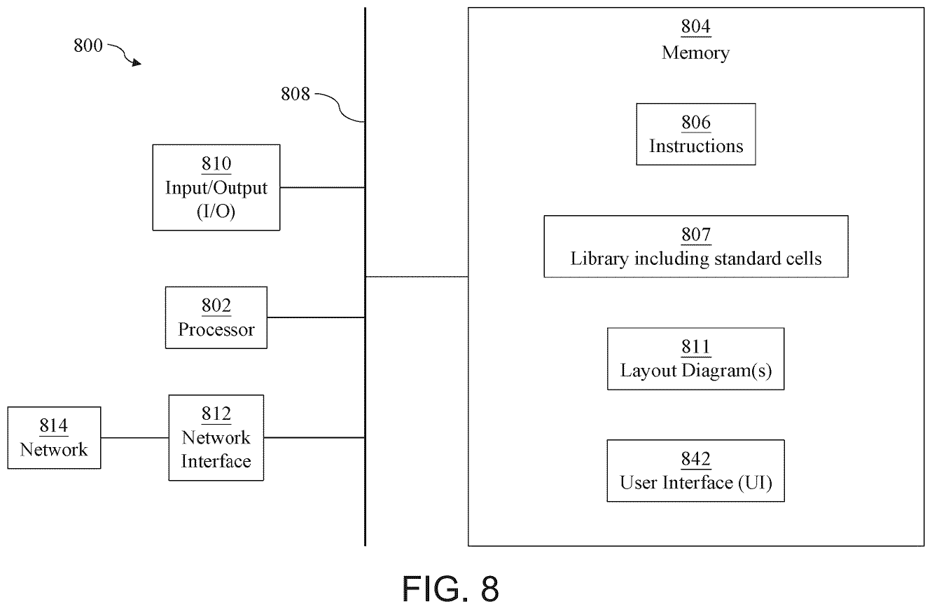

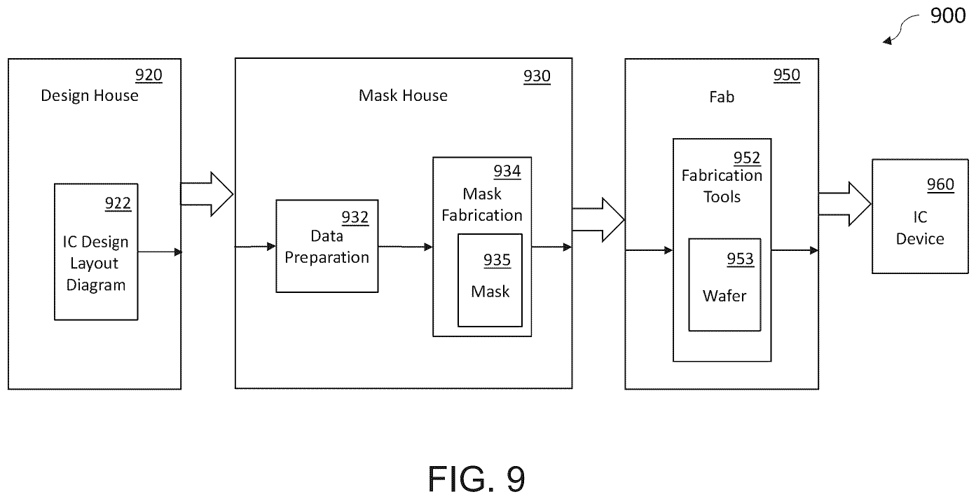

The method of flowchart (flow diagram) 600 is implementable, for example, using EDA system 800 (FIG. 8, discussed below) and an IC manufacturing system 900 (FIG. 9, discussed below), in accordance with some embodiments. Examples of a device which can be manufactured according to the method of flowchart 600 include devices based on the layout diagrams disclosed herein, or the like.

In FIG. 6, the method of flowchart 600 includes blocks 602-604. At block 602, a layout diagram is generated which, among other things, includes one or more of layout diagrams disclosed herein, layout diagrams corresponding to one or more of the devices disclosed herein, or the like. Block 602 is implementable, for example, using EDA system 800 (FIG. 8, discussed below), in accordance with some embodiments. From block 602, flow proceeds to block 604.

At block 604, based on the layout diagram, at least one of (A) one or more photolithographic exposures are made or (b) one or more photolithography masks are fabricated or (C) one or more components in a layer of a device, e.g., a semiconductor device is fabricated. See discussion below of IC manufacturing system 900 in FIG. 9 below.

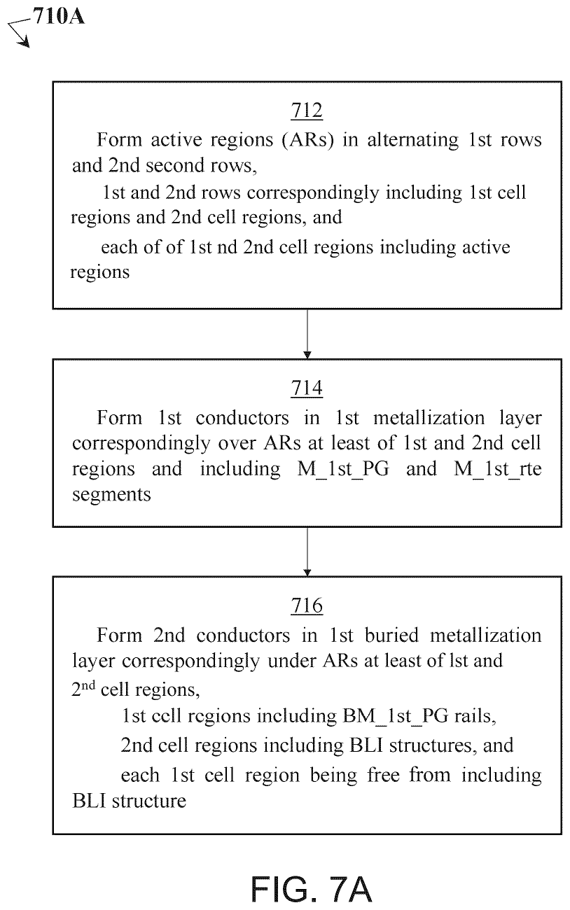

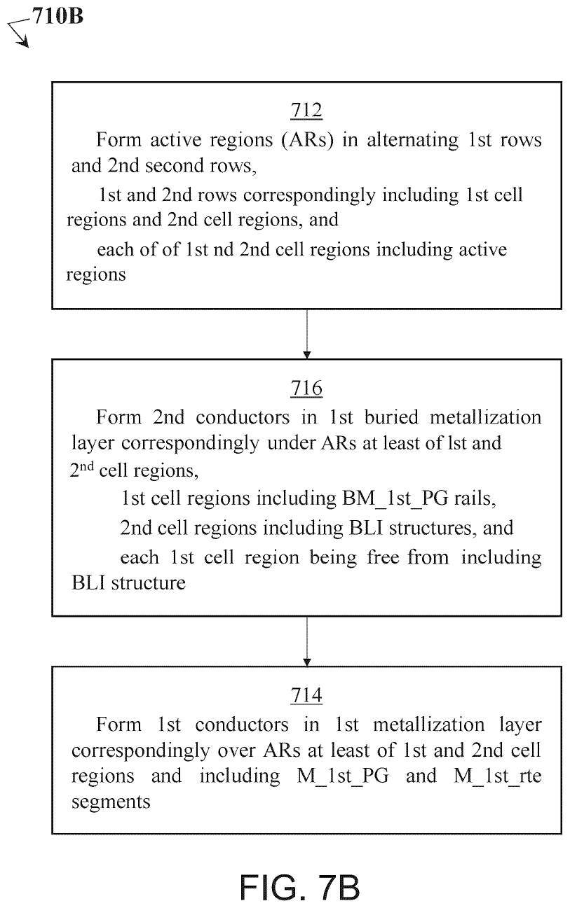

FIG. 7A is a flowchart 710A of a method of fabricating a device, in accordance with some embodiments.

Flowchart 710A is an example of block 604 of FIG. 6. Flowchart 710A includes blocks 712-716. Flowchart 710A shows the following sequence: block 712→block 714→block 716. In some embodiments, other sequences of blocks 712-720 are provided (FIG. 7B). Examples provided in the context of flowchart 710A assume first, second and third orthogonal directions that are, e.g., correspondingly parallel to the X-axis, Y-axis and Z-axis. The method of flowchart 710A is implementable, for example, using IC manufacturing system 900 (FIG. 9, discussed below), in accordance with some embodiments. Examples of a device which can be manufactured according to the method of flowchart 710A include devices based on the layout diagrams disclosed herein, or the like.

At block 712, active regions are formed in alternating first rows and second rows, where the first and second rows hat correspondingly include first cell regions and second cell regions, and where each of the first cell regions and second cell regions correspondingly includes active regions. Examples of the active regions include AR structures 235D1(1), 235D1(2), 235D2(1) and 235D2(2) of FIG. 2B, or the like. Examples of the first rows are odd rows RW1, RW3 and RW5 in FIG. 1A, RW7 and RW9 in FIGS. 1B-1C, or the like. Examples of the second rows are even rows RW2, RW4 and RW6 in FIG. 1A, RW8 and RW10 in FIGS. 1B-1C, or the like. Examples of the first cell regions include first cell regions 102(1)-102(8) of FIG. 1A, 102(9)-102(12) of FIGS. 1B-1C, or the like. Examples of the second cell regions include 104(1)-104(7) of FIG. 1A, 104(8)-104(11) of FIGS. 1B-1C, or the like. From block 712, flow proceeds to block 714.

At block 714, first conductors are formed in a first metallization layer over the active regions, the first conductors including, in each of the first cell regions and the second cell regions, first and second power grid (PG) segments, and one or more routing (RTE) segments. An example of the first metallization layer is layer MET0 108 of FIGS. 1A-1C, 208 of FIGS. 2A-2B, or the like. Examples of the first PG segments include portions of M0_PG segments 112 in upper zones of first cell regions 102(1)-102(8) of FIG. 1A, and more generally in upper zones of odd rows RW1-RW5 of FIG. 1A, in upper zones of first cell regions 102(9)-102(12) of FIG. 1B, and more generally in upper zones of odd rows RW7-RW9 of FIG. 1B, the portion of M0_PG segment 212 in row RW5 of FIGS. 2A-2B, or the like. Examples of the second PG segments include portions of M0_PG segments 112 in lower zones of first cell regions 102(1)-102(8) of FIG. 1A, and more generally in lower zones of odd rows RW1-RW5 of FIG. 1A, in lower zones of first cell regions 102(9)-102(12) of FIG. 1B, and more generally in lower zones of odd rows RW7-RW9 of FIG. 1B, the portion of M0_PG segment 212 in row RW3 of FIGS. 2A-2B, or the like. Examples of the M0_rte segments include M0_rte segments 114 in FIGS. 1A-1C, M0_rte segments 115 in FIGS. 1B-1C, M0_rte segments 116 in FIG. 1C, M0_rte segments 214 in FIGS. 2A-2B, or the like. From block 714, flow proceeds to block 716.

At block 716, first buried conductors are formed in a first buried metallization layer under the active regions, the first buried conductors including: in each of the first cell regions, first and second buried PG (BPG) segments; and in each of the second cell regions, one or more buried local interconnect (BLI) structures, each of the first cell regions being free from including a BLI structure. An example of the first buried metallization layer is layer BMET0 209 of FIGS. 2A-2B, or the like. Examples of the first BPG segments include BM0_PG rails 118 in upper zones of first cell regions 102(1)-102(8) of FIG. 1A, and more generally in upper zones of odd rows RW1-RW5 of FIG. 1A, in upper zones of first cell regions 102(9)-102(12) of FIG. 1B, and more generally in upper zones of odd rows RW7-RW9 of FIG. 1B, the portion of BM0_PG rail 218(2) in row RW5 of FIGS. 2A-2B, or the like. Examples of the second PG segments include BM0_PG rails 118 in lower zones of first cell regions 102(1)-102(8) of FIG. 1A, and more generally in lower zones of odd rows RW1-RW5 of FIG. 1A, in lower zones of first cell regions 102(9)-102(12) of FIG. 1B, and more generally in lower zones of odd rows RW7-RW9 of FIG. 1B, the portion of BM0_PG rail 218(1) in row RW3 of FIGS. 2A-2B, or the like.

Examples of the BLI structure includes BM0_LI structures 120(1)-120(8) in FIG. 1A, 120(9)-120(14) in FIGS. 1B-1C, 220(1) in FIGS. 2A-2B, or the like. Examples of first cell regions being free from including a BLI structure include first cell regions 102(1)-102(8) of FIG. 1A, 102(9)-102(12) of FIGS. 1B-1C, or the like.

In some embodiments, the forming first conductors of block 714 locates the first and second PG segments correspondingly adjacent to first (e.g., top) and second (e.g., bottom) sides correspondingly of the first cell regions and the second cell regions relative to a given direction, e.g., parallel to the Y-axis.

In some embodiments, the forming first buried conductors of block 716 locates each of the first and second BPG segments of each of the second cell regions correspondingly adjacent to the first (e.g., top) and second (e.g., bottom) sides correspondingly of the first cell regions relative to a given direction, e.g., parallel to the Y-axis.

In some embodiments, the forming first conductors of block 714 forms each of the first and second BPG segments to be wider than each of the first and second PG segments relative to a given direction, e.g., parallel to the Y-axis. Examples of each of the first and second BPG segments being wider than each of the first and second PG segments include each of BM0_PG rails 218(1) and 218(2) being wider than each of M0_PG segments 212 in FIGS. 2A-2B, or the like.

In some embodiments, the forming first conductors of block 714 forms at least a portion of at least one of the one or more BLI structures to be wider than each of the first and second BPG segments. Examples of BLI structures having at least a portion that is wider than each of the first and second BPG segments include portions of each of BLI structures BM0_LI structures 120(1)-120(2), 120(4)-120(5), 120(7)-120(8) of FIG. 1A and 120(9) and 120 (12 of FIGS. 1B-1C which are wider than each of BM0_PG rails 118 in FIGS. 1A-1C, BM0_LI structure 220(1) of FIGS. 2A-2B which is wider than each of BM0_PG rails 218(1)-218(2) of FIGS. 2A-2B, or the like.

In some embodiments, the forming first conductors of block 714 also forms at least one of the one or more BLI structures to include a portion that extends across a central zone of the corresponding second cell regions. Examples of such BLI structures include BM0_LI structures 120(1)-120(2), 120(4)-120 (50, 120(7)-120(9) and 120(12) in corresponding second cell regions 104(1)-104(2), 104(4), 104(4) and 104(6)-104(7), or the like.

In some embodiments, the forming active regions of block 712 forms at least one of the second cell regions to include two or more BLI structures. Examples of such second cell regions include second cell regions 104(4) of FIG. 1A and 104(9) and 104(11) of FIGS. 1B-1C that correspondingly include BM0_LI structures 120(4) & 120(5) of FIG. 1A and 120(10) & 120(11) and 120(13) & 120(14) of FIGS. 1B-1C.

In some embodiments, the forming active regions of block 712 forms a first one of the first cell regions and a first one of the second cell regions, and further forms the first first cell region and the first second cell region to have substantially a same width and to be aligned to each other, and wherein the first first cell region and the first second cell region comprise a larger cell region. Examples of the first first cell region and the first second cell region include the following pairings: first cell region 102(1) & second cell region 104(2) of FIG. 1A; first first cell region 102(7) & second cell region 104(6) of FIG. 1A; first first cell region 102(9) & second cell region 104(9) of FIGS. 1B-1C; and first first cell region 102(11) & first second cell region 104(11) of FIGS. 1B-1C. The noted pairings correspondingly comprise tall cell regions 106(1)-106(2) of FIG. 1A and 106(3)-106(4) of FIGS. 1B-1C.

In some embodiments, the forming active regions of block 712 forms at least one of the second rows to further include one or more of the first cell regions. Examples of such second rows include even rows RW8 and RW10 of FIGS. 1B-1C that additionally include corresponding first cell regions 102(10) and 102(12).

In some embodiments, the forming active regions of block 712 forms at least one of the second cell regions so that one of the one or more BLI structures has a concave polygon shape. Examples of such second cell regions include second cell regions 104(1), 104(4) and 104(7) of FIG. 1A and 104(8) and 104(10) of FIGS. 1B-1C that correspondingly include concave polygon BM0_LI structures 120(1), 120(4)-120(5) and 120(8) of FIG. 1A and 120(9) and 120(12) of FIGS. 1B-1C.

In some embodiments, the concave polygon shape of at least one of the one or more BLI structures is a P-shape, a Z-shape or a U-shape. Examples of P-shape BLI structures include P-shape BM0_LI structures 120(1), 120(4) and 120(8) of FIG. 1A, or the like. Examples of the Z-shape BLI structures include Z-shape BM0_LI structures 120(9) and 120(12) of FIGS. 1B-1C, or the like. An example of a U-shape BLI structure includes U-shape BM0_LI structure 120(5) of FIG. 1A, or the like.

In some embodiments, the forming active regions of block 712 forms at least one of the second cell regions so that one of the one or more BLI structures has a convex polygon shape. Examples of such second cell regions include second cell regions 104(2), 104(3) and 104(5) of FIG. 1A and 104(9) and 104(11) of FIGS. 1B-1C that correspondingly include convex polygon BM0_LI structures 120(2), 120(3) and 120(6)-120(7) of FIG. 1A and 120(10) & 120(11) and 120(13) & 120(14) of FIGS. 1B-1C. In some embodiments, the convex polygon shape of at least one of the one or more BLI structures of at least one of the second cell regions has a tall-rectangle shape, where the tall-rectangle shape is taller than a minimum width for a conductive segment in the first buried metallization layer relative to a given direction, e.g., parallel to the Y-axis. Examples of tall rectangular BLI structures include BM0_LI structures 120(2) and 120(7) in corresponding second cell regions 104(2) and 104(6).

In some embodiments, the sequence of flow in flowchart 710A is described as forming front side layers before back side layers. An example of the front side is front side 211F in FIGS. 2A-2B, or the like. An example of the back side is back side 211R in FIGS. 2A-2B, or the like.

FIG. 7B is a flowchart 710B of a method of fabricating a device, in accordance with some embodiments.

Flowchart 710B is similar to flowchart 710A of FIG. 7A in that, e.g., flowchart 710B includes the same blocks as flowchart 710, namely blocks 712-716. Flowchart 710B differs from flowchart 710A in that flowchart 710B shows a different sequence of flow through blocks 712-716 as compared to the sequence shown in flowchart 710A.

In FIG. 7B, flowchart 710B shows the following sequence: block 712→block 716→block 716. In some embodiments, the sequence of flowchart 710B is described as forming back side layers before front side layers.

FIG. 8 is a block diagram of an electronic design automation (EDA) system 800 in accordance with some embodiments.

In some embodiments, EDA system 800 includes an automatic placement and routing (APR) system. In some embodiments, EDA system 800 is a general purpose computing device including a hardware processor 802 and a non-transitory, computer-readable storage medium 804. Storage medium 804, amongst other things, is encoded with, i.e., stores, computer program code 806, i.e., a set of executable instructions. Execution of instructions 806 by hardware processor 802 represents (at least in part) an EDA tool which implements a portion or all of, e.g., methods such as the methods disclosed herein of generating layout diagrams, methods of generating layout diagrams such as the layout diagrams disclosed herein or layout diagrams corresponding to the devices disclosed herein, or the like, in accordance with one or more embodiments (hereinafter, the noted processes and/or methods).

Storage medium 804, amongst other things, stores layout diagrams 811 such as the layout diagrams disclosed herein, other the like.

Processor 802 is electrically coupled to computer-readable storage medium 804 via a bus 808. Processor 802 is further electrically coupled to an I/O interface 810 by a bus 808. A network interface 812 is further electrically connected to processor 802 via bus 808. Network interface 812 is connected to a network 814, so that processor 802 and computer-readable storage medium 804 are capable of connecting to external elements via network 814. Processor 802 is configured to execute computer program code 806 encoded in computer-readable storage medium 804 in order to cause system 800 to be usable for performing a portion or all of the noted processes and/or methods. In one or more embodiments, processor 802 is a central processing unit (CPU), a multi-processor, a distributed processing system, an application specific integrated circuit (ASIC), and/or a suitable processing unit.

In one or more embodiments, computer-readable storage medium 804 is an electronic, magnetic, optical, electromagnetic, infrared, and/or a semiconductor system (or apparatus or device). For example, computer-readable storage medium 804 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 804 includes a compact disk-read only memory (CD-ROM), a compact disk-read/write (CD-R/W), and/or a digital video disc (DVD).

In one or more embodiments, storage medium 804 stores computer program code 806 configured to cause system 800 (where such execution represents (at least in part) the EDA tool) to be usable for performing a portion or all of the noted processes and/or methods. In one or more embodiments, storage medium 804 further stores information which facilitates performing a portion or all of the noted processes and/or methods. In one or more embodiments, storage medium 804 stores library 807 of standard cells including such standard cells as disclosed herein. In some embodiments, storage medium 804 stores one or more layout diagrams 811.

EDA system 800 includes I/O interface 810. I/O interface 810 is coupled to external circuitry. In one or more embodiments, I/O interface 810 includes a keyboard, keypad, mouse, trackball, trackpad, touchscreen, and/or cursor direction keys for communicating information and commands to processor 802.

EDA system 800 further includes network interface 812 coupled to processor 802. Network interface 812 allows system 800 to communicate with network 814, to which one or more other computer systems are connected. Network interface 812 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 800.

System 800 is configured to receive information through I/O interface 810. The information received through I/O interface 810 includes one or more of instructions, data, design rules, libraries of standard cells, and/or other parameters for processing by processor 802. The information is transferred to processor 802 via bus 808. EDA system 800 is configured to receive information related to a user interface (UI) through I/O interface 810. The information is stored in computer-readable medium 804 as UI 842.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 800. In some embodiments, a layout which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 9 is a block diagram of an integrated circuit (IC) manufacturing system 900, and an IC manufacturing flow associated therewith, in accordance with some embodiments.

In some embodiments, based on the layout diagram generated by block 602 of FIG. 6, the IC manufacturing system 900 implements block 604 of FIG. 6 wherein at least one of (A) one or more semiconductor masks or (B) at least one component in a layer of an inchoate semiconductor integrated circuit is fabricated using manufacturing system 900. In some embodiments, the IC manufacturing system 900 implements the flowcharts of FIGS. 7A-7B.

In FIG. 9, IC manufacturing system 900 includes entities, such as a design house 920, a mask house 930, and an IC manufacturer/fabricator (“fab”) 950, that interact with one another in the design, development, and manufacturing cycles and/or services related to manufacturing an IC device 960. The entities in system 900 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and supplies services to and/or receives services from one or more of the other entities. In some embodiments, two or more of design house 920, mask house 930, and IC fab 950 is owned by a single larger company. In some embodiments, two or more of design house 920, mask house 930, and IC fab 950 coexist in a common facility and use common resources.

Design house (or design team) 920 generates an IC design layout 922. IC design layout 922 includes various geometrical patterns designed for an IC device 960. The geometrical patterns correspond to patterns of metal, oxide, or semiconductor layers that make up the various components of IC device 960 to be fabricated. The various layers combine to form various IC features. For example, a portion of IC design layout 922 includes various IC features, such as an active region, gate terminal, source and drain, metal lines or vias of an interlayer interconnection, and openings for bonding pads, to be formed in a semiconductor substrate (such as a silicon wafer) and various material layers disposed on the semiconductor substrate. Source/drain region(s) may refer to a source or a drain, individually or collectively, dependent upon the context. Design house 920 implements a proper design procedure to form IC design layout 922. The design procedure includes one or more of logic design, physical design or place and route. IC design layout 922 is presented in one or more data files having information of the geometrical patterns. For example, IC design layout 922 is expressed in a GDSII file format or DFII file format.

Mask house 930 includes data preparation 932 and mask fabrication 934. Mask house 930 uses IC design layout 922 to manufacture one or more masks 935 to be used for fabricating the various layers of IC device 960 according to IC design layout 922. Mask house 930 performs mask data preparation 932, where IC design layout 922 is translated into a representative data file (“RDF”). Mask data preparation 932 supplies the RDF to mask fabrication 934. Mask fabrication 934 includes a mask writer. A mask writer converts the RDF to an image on a substrate, such as a mask (reticle) or a semiconductor wafer. The design layout is manipulated by mask data preparation 932 to comply with particular characteristics of the mask writer and/or requirements of IC fab 950. In FIG. 9, mask data preparation 932, mask fabrication 934, and mask 935 are illustrated as separate elements. In some embodiments, mask data preparation 932 and mask fabrication 934 are collectively referred to as mask data preparation.

In some embodiments, mask data preparation 932 includes optical proximity correction (OPC) which uses lithography enhancement techniques to compensate for image errors, such as those that can arise from diffraction, interference, other process effects and the like. OPC adjusts IC design layout 922. In some embodiments, mask data preparation 932 includes further resolution enhancement techniques (RET), such as off-axis illumination, sub-resolution adjust features, phase-shifting masks, other suitable techniques, and the like or combinations thereof. In some embodiments, inverse lithography technology (ILT) is further used, which treats OPC as an inverse imaging problem.

In some embodiments, mask data preparation 932 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during mask fabrication 934, which may undo part of the modifications performed by OPC in order to meet mask creation rules.

In some embodiments, mask data preparation 932 includes lithography process checking (LPC) that simulates processing that will be implemented by IC fab 950 to fabricate IC device 960. LPC simulates this processing based on IC design layout 922 to fabricate a simulated manufactured device, such as IC device 960. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been fabricated by LPC, if the simulated device is not close enough in shape to satisfy design rules, OPC and/or MRC are be repeated to further refine IC design layout 922.

The above description of mask data preparation 932 has been simplified for the purposes of clarity. In some embodiments, mask data preparation 932 includes additional features such as a logic operation (LOP) to modify the IC design layout according to manufacturing rules. Additionally, the processes applied to IC design layout 922 during data preparation 932 may be executed in a variety of different orders.

After mask data preparation 932 and during mask fabrication 934, a mask 935 or a group of masks 935 are fabricated based on the modified IC design layout. In some embodiments, an electron-beam (e-beam) or a mechanism of multiple e-beams is used to form a pattern on a mask (photomask or reticle) based on the modified IC design layout. The masks are formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask is an attenuated PSM or alternating PSM. The mask(s) generated by mask fabrication 934 is used in a variety of processes. For example, such a mask(s) is used in an ion implantation process to form various doped regions in the semiconductor wafer, in an etching process to form various etching regions in the semiconductor wafer, and/or in other suitable processes.

IC fab 950 is an IC fabrication business that includes one or more manufacturing facilities for the fabrication of a variety of different IC products. In some embodiments, IC fab 950 is a semiconductor foundry. For example, there may be a manufacturing facility for the front end fabrication of a plurality of IC products (front-end-of-line (FEOL) fabrication), while a second manufacturing facility may supply the back end fabrication for the interconnection and packaging of the IC products (back-end-of-line (BEOL) fabrication), and a third manufacturing facility may supply other services for the foundry business.

IC fab 950 uses mask (or masks) 935 fabricated by mask house 930 to fabricate IC device 960 using fabrication tools 952. Thus, IC fab 950 at least indirectly uses IC design layout 922 to fabricate IC device 960. In some embodiments, a semiconductor wafer 953 is fabricated by IC fab 950 using mask (or masks) 935 to form IC device 960. Semiconductor wafer 953 includes a silicon substrate or other proper substrate having material layers formed thereon. Semiconductor wafer further includes one or more of various doped regions, dielectric features, multilevel interconnects, and the like (formed at subsequent manufacturing steps).

In some embodiments, a device includes: alternating first rows and second rows correspondingly including first cell regions and second cell regions; each of the first cell regions and second cell regions correspondingly including active regions; in a first metallization layer over the active regions: each of the first cell regions and the second cell regions including: first and second power grid (PG) segments; and one or more routing (RTE) segments; and in a first buried metallization layer under the active regions: each of the first cell regions including: first and second buried PG (BPG) segments; and each of the second cell regions including: one or more buried local interconnect (BLI) structures; and each of the first cell regions being free from including a BLI structure.

In some embodiments, the first rows and the second rows extend in a first direction; each of the first and second PG segments, the one or more RTE segments, the first and second BPG segments, and at least a portion of each of the one or more BLI structures, extends in the first direction; and relative to a second direction perpendicular to the first direction, the first and second PG segments are correspondingly adjacent to first and second sides correspondingly of the first cell regions and the second cell regions.

In some embodiments, relative to the first direction, each of the first and second BPG segments of each of the second cell regions is correspondingly adjacent to the first and second sides correspondingly of the first cell regions.

In some embodiments, relative to a second direction perpendicular to the first direction, each of the first and second BPG segments is wider than each of the first and second PG segments.

In some embodiments, relative to a second direction perpendicular to the first direction, at least a portion of at least one of the one or more BLI structures is wider than each of the first and second BPG segments.

In some embodiments, at least one of the second cell regions includes two or more BLI structures.

In some embodiments, the first rows and the second rows extend in a first direction; each of the first and second PG segments, the one or more RTE segments, the first and second BPG segments, and at least a portion of each of the one or more BLI structures, extends in the first direction; and relative to a second direction perpendicular to the first direction, at least one of the one or more BLI structures includes a portion that extends across a central zone of the corresponding second cell region.

In some embodiments, the first rows and the second rows extend in a first direction; relative to a second direction perpendicular to the first direction, a first one of the first cell regions and a first one of the second cell regions abut each other; relative to the first direction, the first first cell region and the first second cell region have substantially a same width and are aligned to each other; and the first first cell region and the first second cell region comprise a larger cell region.

In some embodiments, the first second cell region further includes: third and fourth BPG segments.

In some embodiments, at least one of the second rows further includes: one or more of the first cell regions.

In some embodiments, in at least one of the second cell regions, at least one of the one or more BLI structures has a concave polygon shape.

In some embodiments, the concave polygon shape of at least one of the one or more BLI structures of the at least one of the second cell regions has: a P-shape; a Z-shape; or a U-shape.

In some embodiments, in at least one of the second cell regions, at least one of the one or more BLI structures has a convex polygon shape.

In some embodiments, the convex polygon shape of at least one of the one or more BLI structures of at least one of the second cell regions has a tall-rectangle shape; and relative to a second direction perpendicular to the first direction, the tall-rectangle shape is taller than a minimum width for a conductive segment in the first buried metallization layer.

In some embodiments, a method (of forming a device) includes: forming active regions in alternating first rows and second rows, the first and second rows correspondingly including first cell regions and second cell regions, each of the first cell regions and second cell regions correspondingly including active regions; forming first conductors in a first metallization layer over the active regions, the first conductors including: in each of the first cell regions and the second cell regions, first and second power grid (PG) segments, and one or more routing (RTE) segments; and forming first buried conductors in a first buried metallization layer under the active regions, the first buried conductors including: in each of the first cell regions, first and second buried PG (BPG) segments; and in each of the second cell regions, one or more buried local interconnect (BLI) structures; and the forming first buried conductors further including: configuring each of the first cell regions to be free from including a BLI structure.

In some embodiments, the first rows and the second rows extend in a first direction; the forming first conductors forms each of the first and second PG segments and the one or more RTE segments to extend in the first direction; and the forming first buried conductors forms the first and second BPG segments and at least a portion of each of the one or more BLI structures to extend in the first direction; and relative to a second direction perpendicular to the first direction, the forming first conductors locates the first and second PG segments correspondingly adjacent to first and second sides correspondingly of the first cell regions and the second cell regions.

In some embodiments, relative to the first direction, the forming first buried conductors locates each of the first and second BPG segments of each of the second cell regions correspondingly adjacent to the first and second sides correspondingly of the first cell regions.

In some embodiments, relative to a second direction perpendicular to the first direction, the forming first buried conductors forms each of the first and second BPG segments to be wider than each of the first and second PG segments.

In some embodiments, relative to a second direction perpendicular to the first direction, the forming first buried conductors forms at least a portion of at least one of the one or more BLI structures to be wider than each of the first and second BPG segments.

In some embodiments, a device includes: alternating first rows and second rows correspondingly including first cell regions and second cell regions; each of the first cell regions and second cell regions correspondingly including active regions; in a first metallization layer over the active regions: each of the first cell regions and the second cell regions including: first and second power grid (PG) segments; and one or more routing (RTE) segments; and in a first buried metallization layer under the active regions: each of the first cell regions including: first and second buried PG (BPG) segments; and each of the second cell regions including: one or more buried local interconnect (BLI) structures; each of the first cell regions being free from including a BLI structure; and in at least one of the second cell regions, at least one of the one or more buried BLI structures has a shape different than a minimal width rectangular shape of an instance of the one or more buried BLI structures, the minimal rectangular shape having a minimum width for a conductive segment in the first buried metallization layer.

In some embodiments, in at least one of the second cell regions, at least one of the one or more BLI structures has a concave polygon shape.

In some embodiments, the concave polygon shape of at least one of the one or more BLI structures of the at least one of the second cell regions has: a P-shape; a Z-shape; or a U-shape.

In some embodiments, in at least one of the second cell regions, at least one of the one or more BLI structures has a convex polygon shape.

In some embodiments, the convex polygon shape of at least one of the one or more BLI structures of at least one of the second cell regions has a tall-rectangle shape; and relative to a second direction perpendicular to the first direction, the tall-rectangle shape is taller than a minimum width for a conductive segment in the first buried metallization layer.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

What is claimed is:

1. A device comprising:
alternating first rows and second rows correspondingly including first cell regions and second cell regions;
each of the first cell regions and second cell regions correspondingly including active regions;
in a first metallization layer over the active regions:
each of the first cell regions and the second cell regions including:
first and second power grid (PG) segments; and
one or more routing (RTE) segments; and
in a first buried metallization layer under the active regions:
each of the first cell regions including:
first and second buried PG (BPG) segments; and
each of the second cell regions including:
one or more buried local interconnect (BLI) structures; and
each of the first cell regions being free from including a BLI structure.

2. The device of claim 1, wherein:
the first rows and the second rows extend in a first direction;
each of the first and second PG segments, the one or more RTE segments, the first and second BPG segments, and at least a portion of each of the one or more BLI structures, extends in the first direction; and
relative to a second direction perpendicular to the first direction,
the first and second PG segments are correspondingly adjacent to first and second sides correspondingly of the first cell regions and the second cell regions.

3. The device of claim 2, wherein:
relative to the first direction,
each of the first and second BPG segments of each of the second cell regions is correspondingly adjacent to the first and second sides correspondingly of the first cell regions.

4. The device of claim 1, wherein:
relative to a second direction perpendicular to the first direction,
each of the first and second BPG segments is wider than each of the first and second PG segments.

5. The device of claim 1, wherein:
relative to a second direction perpendicular to the first direction,
at least a portion of at least one of the one or more BLI structures is wider than each of the first and second BPG segments.

6. The device of claim 1, wherein:
at least one of the second cell regions includes two or more BLI structures.

7. The device of claim 1, wherein:
the first rows and the second rows extend in a first direction;
each of the first and second PG segments, the one or more RTE segments, the first and second BPG segments, and at least a portion of each of the one or more BLI structures, extends in the first direction; and
relative to a second direction perpendicular to the first direction,
at least one of the one or more BLI structures includes a portion that extends across a central zone of the corresponding second cell region.

8. The device of claim 1, wherein:
at least one of the second rows further includes:
one or more of the first cell regions.

9. The device of claim 1, wherein:
in at least one of the second cell regions, at least one of the one or more BLI structures has a concave polygon shape.

10. The device of claim 1, wherein:
in at least one of the second cell regions, at least one of the one or more BLI structures has a convex polygon shape.

11. A method of forming a device, the method comprising:
forming active regions in alternating first rows and second rows, the first and second rows correspondingly including first cell regions and second cell regions,
each of the first cell regions and second cell regions correspondingly including active regions;
forming first conductors in a first metallization layer over the active regions, the first conductors including:
in each of the first cell regions and the second cell regions,
first and second power grid (PG) segments, and
one or more routing (RTE) segments; and
forming first buried conductors in a first buried metallization layer under the active regions, the first buried conductors including:
in each of the first cell regions,
first and second buried PG (BPG) segments; and
in each of the second cell regions,
one or more buried local interconnect (BLI) structures; and
the forming first buried conductors further including:
configuring each of the first cell regions to be free from including a BLI structure.

12. The method of claim 11, wherein:
the first rows and the second rows extend in a first direction;
the forming first conductors forms each of the first and second PG segments and the one or more RTE segments to extend in the first direction; and
the forming first buried conductors forms the first and second BPG segments and at least a portion of each of the one or more BLI structures to extend in the first direction; and
relative to a second direction perpendicular to the first direction,
the forming first conductors locates the first and second PG segments correspondingly adjacent to first and second sides correspondingly of the first cell regions and the second cell regions.

13. The method of claim 12, wherein:
relative to the first direction,
the forming first buried conductors locates each of the first and second BPG segments of each of the second cell regions correspondingly adjacent to the first and second sides correspondingly of the first cell regions.

14. The method of claim 11, wherein:
relative to a second direction perpendicular to the first direction,
the forming first buried conductors forms each of the first and second BPG segments to be wider than each of the first and second PG segments.

15. The method of claim 11, wherein:
relative to a second direction perpendicular to the first direction,
the forming first buried conductors forms at least a portion of at least one of the one or more BLI structures to be wider than each of the first and second BPG segments.

16. A device comprising:
alternating first rows and second rows correspondingly including first cell regions and second cell regions;
each of the first cell regions and second cell regions correspondingly including active regions;
in a first metallization layer over the active regions:
each of the first cell regions and the second cell regions including:
first and second power grid (PG) segments; and
one or more routing (RTE) segments; and
in a first buried metallization layer under the active regions:
each of the first cell regions including:
first and second buried PG (BPG) segments; and
each of the second cell regions including:
one or more buried local interconnect (BLI) structures;
each of the first cell regions being free from including a BLI structure; and
in at least one of the second cell regions, at least one of the one or more buried BLI structures has a shape different than a minimal width rectangular shape of an instance of the one or more buried BLI structures,
the minimal rectangular shape having a minimum width for a conductive segment in the first buried metallization layer.

17. The device of claim 16, wherein:
in at least one of the second cell regions, at least one of the one or more BLI structures has a concave polygon shape.

18. The device of claim 17, wherein:
the concave polygon shape of at least one of the one or more BLI structures of the at least one of the second cell regions has:
a P-shape;
a Z-shape; or
a U-shape.

19. The device of claim 16, wherein:
in at least one of the second cell regions, at least one of the one or more BLI structures has a convex polygon shape.

20. The device of claim 19, wherein:
the convex polygon shape of at least one of the one or more BLI structures of at least one of the second cell regions has a tall-rectangle shape; and
relative to a second direction perpendicular to the first direction, the tall-rectangle shape is taller than a minimum width for a conductive segment in the first buried metallization layer.
